(19) United States
(12) Patent Application Publication
(10) Pub. No.: US 2016/0359107 A1
(43) Pub. Date: Dec. 8, 2016

(54) METHOD OF MANUFACTURING MAGNETORESISTIVE ELEMENT

(71) Applicant: KABUSHIKI KAISHA TOSHIBA, Tokyo (JP)

(72) Inventors: Yuichi OHSAWA, Yokohama-shi (JP); Junichi ITO, Yokohama-shi (JP); Shigeki TAKAHASHI, Yokohama-shi (JP); Saori KASHIWADA, Yokohama-shi (JP); Chikayoshi KAMATA, Kawasaki-shi (JP)

(73) Assignee: KABUSHIKI KAISHA TOSHIBA, Tokyo (JP)

(21) Appl. No.: 15/240,033

(22) Filed: Aug. 18, 2016

Related U.S. Application Data
(63) Continuation of application No. 13/621,978, filed on Sep. 18, 2012.

(30) Foreign Application Priority Data
Mar. 21, 2012 (JP) 2012-064248

(51) Int. Cl. H01L 43/12; H01L 43/02; H01L 43/10; H01L 43/08

(52) U.S. Cl. CPC H01L 43/12; H01L 43/08; H01L 43/02; H01L 43/10

(57) ABSTRACT

According to one embodiment, a method of manufacturing a magnetoresistive element, the method includes forming a first magnetic layer, forming a tunnel barrier layer on the first magnetic layer, forming a second magnetic layer on the tunnel barrier layer, forming a hard mask layer on the second magnetic layer, and patterning the second magnetic layer, the tunnel barrier layer, and the first magnetic layer, with a cluster ion beam using the hard mask layer as a mask, wherein the cluster ion beam comprises cluster ions, cluster sizes of the cluster ions are distributed, and a peak value of the distribution of the cluster sizes is 2 pieces or more and 1000 pieces or less.

### CROSS-REFERENCE TO RELATED APPLICATIONS

This application is based upon and claims the benefit of priority from Japanese Patent Application No. 2012-064248, filed Mar. 21, 2012, the entire contents of which are incorporated herein by reference.

### FIELD

Embodiments described herein relate generally to a method of manufacturing a magnetoresistive element.

### BACKGROUND

A magnetoresistive element is used in a storage device such as a hard disk drive (HDD) and a magnetic random access memory (MRAM). The basic structure of the magnetoresistive element includes three layers of thin films including a magnetic free layer and a magnetic pinned layer which are made of magnetic material and also including a tunnel barrier layer provided therebetween. Information is stored by magnetization states of the magnetic free layer and the magnetic pinned layer.

For the magnetoresistive element, the following two kinds of information storage method (magnetization reversal process) are known: a type in which magnetization reversal process is executed by a magnetic field (magnetic field writing) and a type in which magnetization reversal process is executed by an electric current (spin transfer writing). For the magnetoresistive element, the following two kinds are known as the magnetization states of the magnetic free layer and the magnetic pinned layer: a type in which the magnetization direction is in a direction parallel to the film surface (in-face magnetization) and a type in which the magnetization direction is in a direction perpendicular to the film surface (vertical magnetization).

In recent years, a method has been considered to use a cluster ion beam to pattern the magnetoresistive element and execute a magnetization suppression of a magnetic layer existing at a sidewall portion of the magnetoresistive element.

In this specification, the magnetization suppression includes a magnetization reduction and demagnetization.

In this case, the cluster means an aggregate of atoms or molecules. The atoms or molecules may be of one type or of different types. Alternatively, an aggregate of atoms and molecules may constitute the cluster. When atoms or molecules are gas, the cluster is referred to as gas cluster, and the atoms or molecules are made into one cluster by Van der Waals attraction.

Then, when the cluster is ionized, and energy is given to the cluster at an acceleration voltage, a cluster ion beam can be generated.

However, when the magnetoresistive element is patterned using the cluster ion beam, there are problems in that, e.g., processing accuracy of the magnetoresistive element is reduced because a hard mask is chipped off, and a substantial thickness of the tunnel barrier increases because atoms or molecules comprising cluster ions enter into an interface between a tunnel barrier and a magnetic layer.

When the cluster ion beam is used to execute the magnetization suppression of a magnetic layer existing at a sidewall portion of the magnetoresistive element, there is a problem in that the effective size of the magnetoresistive element varies (edge roughness) caused by variation in dose profiles of cluster ions injected into the sidewall portion of the magnetoresistive element.

The reduction of the processing accuracy of the magnetoresistive element, the increase in the substantial thickness of the tunnel barrier, and variation in the substantial size of the magnetoresistive element described above result in reduction of manufacturing yield of storage devices having magnetoresistive elements and further result in increase of the cost.

### BRIEF DESCRIPTION OF THE DRAWINGS

FIGS. 1 and 2 are figures illustrating the first embodiment of a manufacturing method;

FIG. 3 is a figure illustrating relationship between a cluster size and a mask remaining rate;

FIG. 4 is a figure illustrating relationship between a mask cross section and a mask remaining rate;

FIG. 5 is a figure illustrating relationship between a thickness of a tunnel barrier layer and a cluster size;

FIG. 6 is a figure illustrating relationship between an over ratio and a mask remaining rate;

FIG. 7 is a figure illustrating distribution of cluster sizes;

FIG. 8 is a figure illustrating relationship between a cluster size and a coercive force;

FIG. 9 is a figure illustrating relationship between a cluster size and a taper angle;

FIG. 10 is a figure illustrating the second embodiment of a manufacturing method;

FIGS. 11 and 12 are figures illustrating the third embodiment of manufacturing method;

FIG. 13 is a figure illustrating the fourth embodiment of a manufacturing method;

FIGS. 14 to 19 are figures illustrating the fifth embodiment of a manufacturing method;

FIGS. 20 and 21 are figures illustrating the sixth embodiment of a manufacturing method;

FIG. 22 is a figure illustrating edge roughness;

FIG. 23 is a figure illustrating relationship between a cluster size and an edge roughness;

FIG. 24 is a figure illustrating relationship between a cluster size and a differential ΔLW;

FIGS. 25 to 27 are figures illustrating the seventh embodiment of a manufacturing method;

FIG. 28 is a figure illustrating overview of a GCIB apparatus;

FIG. 29 is a figure illustrating a magnetic memory serving as an example of application; and

FIGS. 30 to 38 are figures illustrating a manufacturing method of a magnetic memory.

### DETAILED DESCRIPTION

In general, according to one embodiment, a method of manufacturing a magnetoresistive element, the method comprises: forming a first magnetic layer; forming a tunnel barrier layer on the first magnetic layer; forming a second magnetic layer on the tunnel barrier layer; forming a hard mask layer on the second magnetic layer; and patterning the second magnetic layer, the tunnel barrier layer, and the first magnetic layer, with a cluster ion beam using the hard mask layer as a mask, wherein the cluster ion beam comprises cluster ions, cluster sizes of the cluster ions are distributed, and a peak value of the distribution of the cluster sizes is 2 pieces or more and 1000 pieces or less.

Hereinafter, embodiments will be described with reference to drawings. In the explanation below, elements having the same functions and configurations will be denoted with the same reference numerals, and they are explained repeatedly only when necessary.

### [Basic Configuration]

The embodiment relates to a manufacturing method using a cluster ion beam to pattern a magnetoresistive element or execute the magnetization suppression of a sidewall portion of the magnetoresistive element.

In a conventional technique, in many cases, the magnetoresistive element is patterned by, e.g., monomer ion beam etching (IBE) using an inactive gas such as Ar.

In this case, the monomer ion beam etching is a method for ionizing an atom, giving energy thereby at an acceleration voltage, and generating a monomer ion beam, which is different from the cluster ion beam according to the embodiments described herein.

It should be noted that the monomer ion beam etching includes reactive ion beam etching.

As is well known, in the patterning of the magnetoresistive element using the monomer ion beam, there is the following problem. During the etching of the magnetic layer, a re-deposition layer of the magnetic layer serving as etched material is formed on a sidewall portion of the magnetoresistive element, and this short-circuits the magnetic free layer and the magnetic pinned layer.

The monomer ion beam causes crystal degradation, crystal strain, and the like, in the magnetoresistive element, and this degrades magnetism characteristics of the magnetoresistive element.

In contrast, the patterning of the magnetoresistive element using the cluster ion beam is capable of resolving problems of the monomer ion beam by patterning different from the monomer ion beam in principle, in the way that the patterning using the cluster ion beam is executed by a multiple collision in an equivalent high temperature/pressure. However, the cluster ion beam etching is not completely free from problems.

For example, in the cluster ion beam etching, it is difficult to fix the cluster size to a fixed value, and in general, the cluster size is distributed. In this case, where the same energy is given to one cluster at an acceleration voltage, variation (distribution) occurs in the energy per atom or molecule in accordance with the cluster size. As a result, etched surface that is not covered with a hard mask is damaged by an atom or molecule having high energy.

In this case, the cluster size is the number of atoms or molecules in a cluster. The method for counting the cluster size is different according to whether an element comprising the cluster is an atom or a molecule.

More specifically, when a cluster is constituted by molecules, the cluster size is counted using the molecule as a basic unit. For example, when Cl₂-gas cluster ions are used, the cluster size is counted in such a manner that one Cl₂ molecule is counted as one. When a cluster is constituted by atoms, the cluster size is counted using the atom as a basic unit. For example, when Ar-gas cluster ions are used, the cluster size is counted in such a manner that one Ar atom is counted as one.

When a cluster ion is made of atoms and molecules in a mixed manner, the cluster size is counted using the atom as a basic unit for the atom and using the molecule as a basic unit for the molecule.

When the magnetoresistive element is patterned using the cluster ion beam, there are the following problems in addition to the above problems. Processing accuracy of the magnetoresistive element is reduced because a hard mask is chipped off, and a substantial thickness of the tunnel barrier increases because atoms or molecules comprising cluster ions enter into an interface between a tunnel barrier and a magnetic layer.

In order to solve this, the cluster size has been considered. As a result, we have found that the peak value of the distribution of the cluster sizes of the cluster ions comprising the cluster ion beam is desirably set at 2 pieces or more and 1000 pieces or less.

As described above, however, when the cluster size is too small, the width of the distribution of the cluster sizes increases, and this increases the distribution of energy per atom or molecule.

Accordingly, the damage to the etched surface (for example, magnetic layer) due to the dispersed energy per atom or molecule is solved by emitting auxiliary GCIB (Gas cluster ion beam) having annealing effect for recovering the damage or by the magnetization suppression (deactivation) of the damaged portion.

For example, the magnetization suppression process is executed after the magnetoresistive element is patterned or while the magnetoresistive element is patterned. This magnetization suppression process is also a technique employed for a magnetoresistive element in which, for example, a magnetic free layer of which magnetization direction is variable is a lower layer (substrate side) and a magnetic pinned layer of which magnetization direction is invariable is an upper layer.

For example, in a magnetoresistive element of a type in which the magnetization direction is perpendicular to the film surface (vertical magnetization), it is known that the magnetism characteristics can be improved when the magnetic free layer is set as the lower layer. In this case, when the horizontal size of the magnetic free layer is more than the horizontal size of the magnetic pinned layer, the magnetization reversal characteristics are deteriorated. Therefore, a portion of the magnetic free layer is executed the magnetization suppression (deactivation) by injecting cluster ions, and the effective size of the magnetic free layer is reduced.

In this magnetization suppression process of the sidewall portion of the magnetoresistive element, the cluster size is also considered. As a result, we have found that the peak value of the distribution of the cluster sizes of the cluster ions comprising the cluster ion beam is desirably set at 2 pieces or more and 1000 pieces or less.

This is because, when this cluster size is employed, this alleviates the variation of the dose profile of cluster ions injected into the sidewall portion of the magnetoresistive element, and thereby, the variation of the effective size of the magnetoresistive element (edge roughness) is reduced.

When 70% or more of all the cluster ions generated during the patterning of the magnetoresistive element are aggregates of 2 to 1000 atoms or 2 to 1000 molecules, i.e., the ratio of cluster ions of which cluster size is more than 1000 pieces (over ratio) is 30% or less, we have confirmed that this is furthermore effective to solve problems such as reduction of the processing accuracy of the magnetoresistive element, the increase in the effective thickness of the tunnel barrier, and the variation in the effective size of the magnetoresistive element described above.

The manufacturing method using the above cluster ion beam is particularly effective when the horizontal size of the magnetoresistive element is equal to or less than 30 nm.

In this case, the horizontal size means the size when the magnetoresistive element is seen from above the magnetoresistive element (above the substrate). For example, if the magnetoresistive element is in a circular shape when it is seen from above the substrate, the horizontal size is the diameter of the circle. If the magnetoresistive element is in a rectangular shape when it is seen from above the substrate, the horizontal size is the length of a side.

### First Embodiment

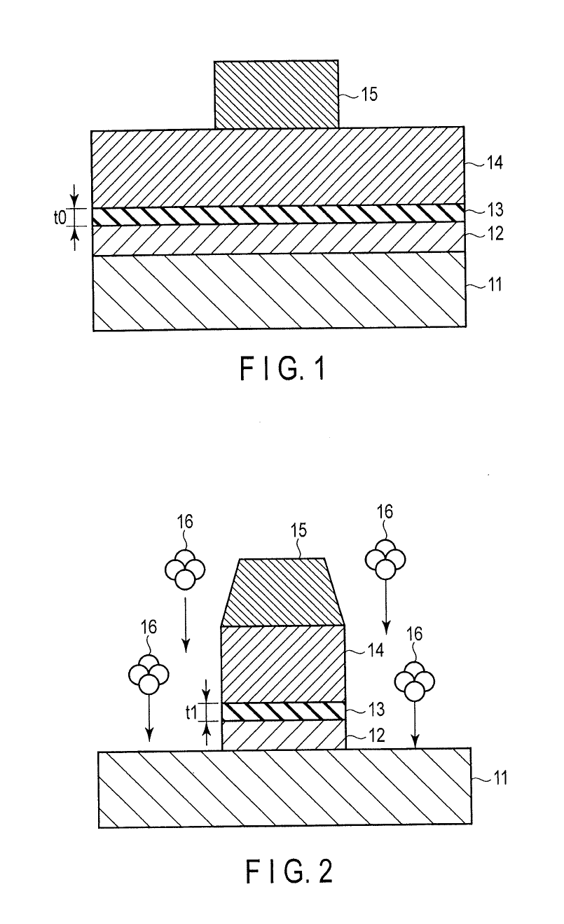

FIGS. 1 and 2 illustrate the first embodiment of a manufacturing method of a magnetoresistive element.

This manufacturing method relates to a patterning of the magnetoresistive element.

First, as illustrated in FIG. 1, for example, first magnetic layer 12, tunnel barrier layer 13, second magnetic layer 14, and hard mask layer 15 are formed in order on underlayer 11 using sputtering method. For example, underlayer 11 serves as a lower electrode, and hard mask layer 15 serves as an upper electrode. For example, each of underlayer 11 and hard mask layer 15 has a metal or alloy.

First and second magnetic layers 12, 14 have one of in-face magnetization and vertical magnetization. One of first and second magnetic layers 12, 14 is a magnetic free layer of which magnetization direction is variable, and the other of first and second magnetic layers 12, 14 is a magnetic pinned layer of which magnetization direction is invariable.

In this case, “the magnetization direction is variable” means that the magnetization direction is changed by applying a magnetic field or a magnetization reversal electric current for reversing the magnetization direction. On the other hand, “the magnetization direction is invariable” means that the magnetization direction is not changed by applying a magnetic field or a magnetization reversal electric current for reversing the magnetization direction.

For example, when first and second magnetic layers 12, 14 have the vertical magnetization, first magnetic layer 12 is desirably a magnetic free layer of which magnetization direction is variable, and second magnetic layer 14 is desirably a magnetic pinned layer of which magnetization direction is invariable (top pin type). In this case, materials (including crystal structure and composition) required to grow a magnetic layer of vertical magnetization are provided on underlayer 11.

For example, first and second magnetic layers 12, 14 are selected from a ferromagnetic material having L1₀ structure or L1₁ structure such as FePd, FePt, CoPd, CoPt, a soft magnetic material such as CoFeB, a ferrimagnetic material such as TbCoFe, and an artificial lattice made of a laminated layer structure including a magnetic material such as NiFe, Co and a nonmagnetic material such as Cu, Pd, Pt.

For example, tunnel barrier layer 13 is magnesium oxide (MgO). A thickness (initial thickness) of tunnel barrier layer 13 at this moment (before cluster ion beam etching) is to. For example, hard mask layer 15 is tantalum (Ta).

When second magnetic layer 14 is used as the magnetic pinned layer, an interfacial layer (IFL) may be formed in addition between tunnel barrier layer 13 and second magnetic layer 14 in the step of forming the above laminated layer structure. This interface layer includes, for example, CoFeB.

When second magnetic layer 14 is used as the magnetic pinned layer, second magnetic layer 14 desirably includes a magnetic layer serving as the magnetic pinned layer and a bias magnetic field layer having an effect of cancelling leakage magnetic field (stray magnetic field) from the magnetic pinned layer. Even in this case, underlayer 11 desirably includes a bias magnetic field layer, too.

Subsequently, as illustrated in FIG. 2, the magnetoresistive element is patterned using lithography and cluster ion beam etching which are well-known techniques.

More specifically, using PEP (Photo engraving process), a photoresist layer is formed on hard mask layer 15, and using this photoresist layer as a mask, hard mask layer 15 is patterned. Thereafter, the photoresist layer is removed.

Subsequently, second magnetic layer 14, tunnel barrier layer 13, and first magnetic layer 12 are etched in order by, for example, GCIB (gas cluster ion beam) etching using hard mask layer 15 as a mask.

This GCIB etching is executed using cluster ion 16 of which peak value of the distribution of the cluster sizes is 2 pieces or more and 1000 pieces or less.

For example, cluster ion 16 includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

With this GCIB etching, the patterning of the magnetoresistive element is completed.

It should be noted that, after the cluster ion beam etching, the thickness of tunnel barrier layer 13 is t1.

### [Relationship Between the Cluster Size and the Mask Remaining Rate]

The relationship between the cluster size of the cluster ion used for patterning the magnetoresistive element and the mask remaining rate of the hard mask layer will be considered.

The magnetoresistive element serving as the sample includes the structure according to the first embodiment explained above.

For example, in FIG. 1, underlayer 11 and hard mask layer 15 are made of Ta, first magnetic layer (magnetic free layer) 12 is made of a laminated layer including [Co/Pt]₆ and CoFeB, tunnel barrier layer 13 is MgO, second magnetic layer (magnetic pinned layer) 14 is a laminated layer including CoFeB, Ta, CoFeB, Tb—Co—Fe, and Ru.

More specifically, the magnetoresistive element has the laminated layer structure including Ta/[Co/Pt]₆/CoFeB/MgO/CoFeB/Ta/CoFeB/Tb—Co—Fe/Ru/Ta, which are arranged from the lower layer to the upper layer.

It should be noted that [Co/Pt]₆ means a structure made by laminating six laminated layers each including a Co layer and a Pt layer, and Tb—Co—Fe means an alloy including Tb, Co, and Fe, wherein the composition ratio thereof is not particularly limited.

The bottom surface of hard mask layer 15 is a circle of which diameter is 25 nm, and hard mask layer 15 is in a pillar shape of which height is 50 nm.

The GCIB etching is executed using a cluster ion including Cl atom and Kr atom (Cl: 20%) cluster ion. The cluster size of the cluster ion has a distribution, and has a peak value (the most common cluster size).

Under such prior conditions, as illustrated in FIG. 2, the magnetoresistive element is patterned by the GCIB etching using hard mask layer 15 as a mask.

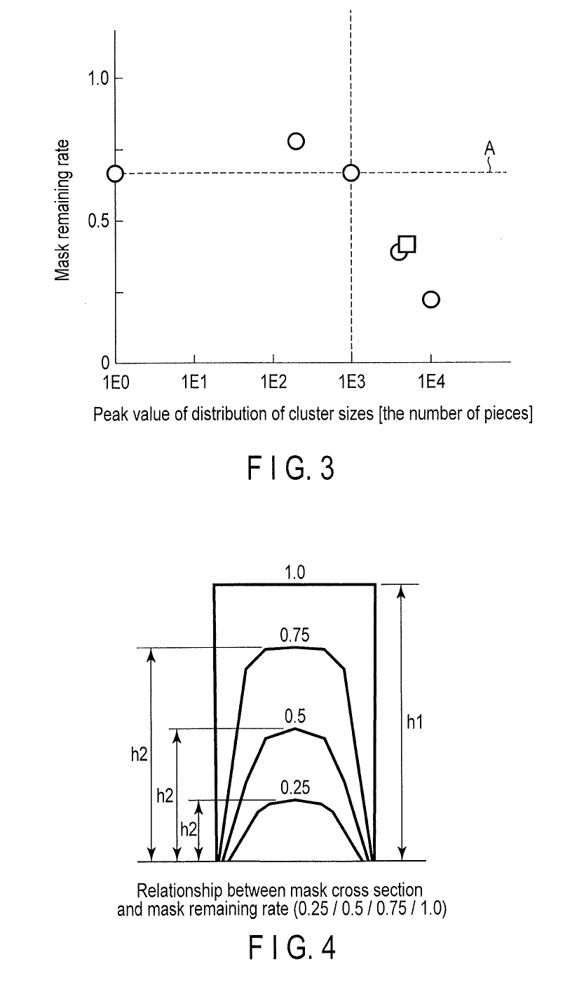

When the relationship between the cluster size and the remaining rate of the hard mask layer (mask remaining rate) was studied, the relationship as illustrated in FIG. 3 was obtained.

However, this result is obtained on the basis of the assumption that, in each of conditions serving as parameters described below, the energy per one atom or molecule in a cluster ion having a cluster size equal to a peak value or the average value thereof is the same (for example, 5 eV per atom or molecule). More specifically, for example, the energy is equally distributed to the atoms or molecules in the cluster ion.

### *Condition 1 (Circular Mark)

The peak value of the distribution of the cluster sizes is 10000 pieces, and the acceleration voltage of the cluster ion is 50 kV. In this case, the energy per one atom or molecule in a cluster ion of which cluster size is 10000 or the average value thereof is 5 eV per atom or molecule.

### *Condition 2 (Circular Mark)

The peak value of the distribution of the cluster sizes is 5000 pieces, and the acceleration voltage of the cluster ion is 25 kV. In this case, the energy per one atom or molecule in a cluster ion of which cluster size is 5000 pieces or the average value thereof is 5 eV per atom or molecule.

### *Condition 3 (Circular Mark)

The peak value of the distribution of the cluster sizes is 1000 pieces, and the acceleration voltage of the cluster ion is 5 kV. In this case, the energy per one atom or molecule in a cluster ion of which cluster size is 1000 pieces or the average value thereof is 5 eV per atom or molecule.

### *Condition 4 (Circular Mark)

The peak value of the distribution of the cluster sizes is 200 pieces, and the acceleration voltage of the cluster ion is 1 kV. In this case, the energy per one atom or molecule in a cluster ion of which cluster size is 200 pieces or the average value thereof is 5 eV per atom or molecule.

### *Condition 5 (Rectangular Mark)

This is a case where the cluster size is not particularly specified (no size selection). In this case, it is the same as the condition 2.

### *Condition 6 (Circular Mark)

The patterning is executed using a monomer ion beam. In a gas atmosphere including Cl atoms and Kr atoms, the magnetoresistive element is patterned by RIBE (Reactive Ion beam Etching) at an acceleration voltage of 500 V. The substrate temperature (stage temperature) is 250 degrees Celsius.

As illustrated in FIG. 4, the mask remaining rate means a ratio (h2/h1) between height h1 of hard mask layer 15 before the GCIB etching (before the RIBE under the condition 6) and height h2 of hard mask layer 15 after the GCIB etching (after the RIBE under the condition 6). This ratio is checked using a cross-sectional transmission electron microscope (XTEM).

As is evident from FIGS. 3 and 4, it is understood that when line A of the mask remaining rate (about 0.7) with the monomer ion beam is adopted as a reference, a better result than that of a conventional monomer ion beam etching can be obtained where the peak value of the distribution of the cluster sizes of cluster ions is 2 pieces or more and 1000 pieces or less.

For example, the mask remaining rate under the condition 1 is about 0.25, and the mask remaining rate under the conditions 2 and 5 is about 0.4, which is a result worse than the conventional monomer ion beam etching. In contrast, the mask remaining rate under the condition 3 is about 0.7, and the mask remaining rate under the condition 4 is about 0.8, which is a result better than the conventional monomer ion beam etching.

It is confirmed that the above result does not depend on the component of the cluster ion.

More specifically, in this example, although the cluster ion including Cl atoms and Kr atoms is used, the same result can be obtained even when, for example, the cluster ion includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

### [Relationship Between the Cluster Size and the Thickness of the Tunnel Barrier Layer]

The relationship between the cluster size of the cluster ion used for patterning the magnetoresistive element and the thickness of the tunnel barrier layer will be considered.

The magnetoresistive element serving as the sample is manufactured under the same prior condition as that of the sample used in the “relationship between the cluster size and the mask remaining rate” explained above. The conditions (condition 1 to condition 6) serving as the parameters are also the same as the above “relationship between the cluster size and the mask remaining rate”.

Under such conditions, as illustrated in FIG. 2, the magnetoresistive element is patterned by the GCIB etching using hard mask layer 15 as a mask.

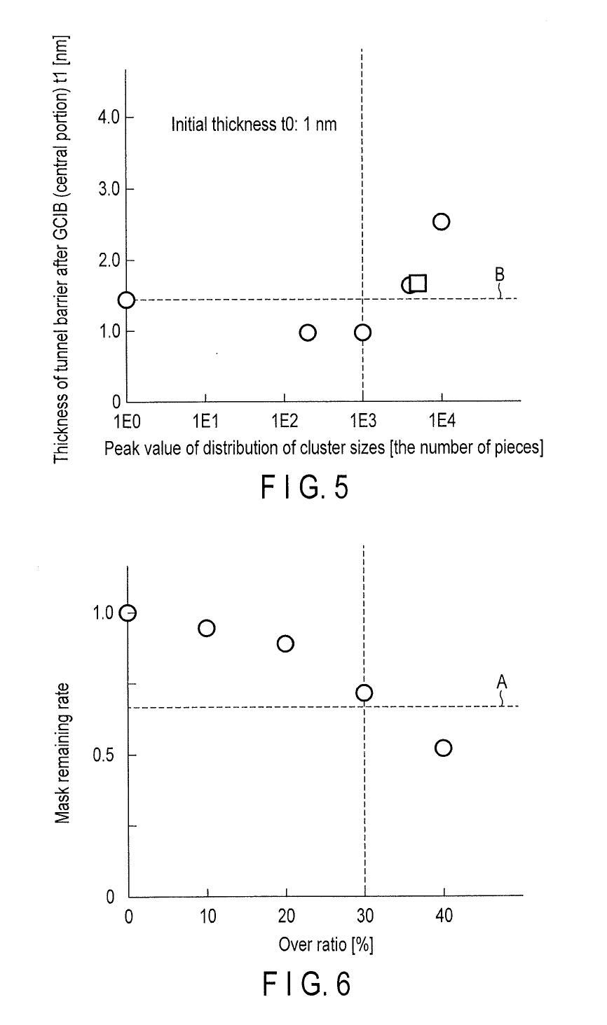

When the relationship between the cluster size and the thickness of the tunnel barrier layer was studied, the relationship as illustrated in FIG. 5 was obtained.

In this case, the thickness of the tunnel barrier layer is the thickness in a central portion when the patterned magnetoresistive element is seen from above. Thickness (central portion) t0 of the tunnel barrier layer of the magnetoresistive element that has not yet patterned is 1 nm.

It should be noted that the thickness (central portion) of the tunnel barrier layer is checked using a cross-sectional transmission electron microscope (XTEM), before the GCIB etching (before the RIBE under the condition 6) and after the GCIB etching (after the RISE under the condition 6).

As is evident from FIG. 5, it is understood that when line B of the thickness (about 1.5 nm) t1 of the tunnel barrier layer after the patterning with the monomer ion beam is adopted as a reference, a better result than that of a conventional monomer ion beam etching can be obtained where the peak value of the distribution of the cluster sizes of cluster ions is 2 pieces or more and 1000 pieces or less.

For example, thickness t1 of the tunnel barrier layer after the GCIB etching under the condition 1 is about 2.8 nm, and thickness t1 of the tunnel barrier layer after the GCIB etching under the conditions 2 and 5 is about 1.7 nm, which are much more than initial thickness t0 (1 nm). This is a result worse than the conventional monomer ion beam etching. In contrast, thickness t1 of the tunnel barrier layer after the GCIB etching under each of the condition 3 and the condition 4 is the same as initial thickness t0 (1 nm) or about 1 nm which is almost the same as initial thickness t0 (1 nm). This is a result better than the conventional monomer ion beam etching.

It is confirmed that the above result does not depend on the component of the cluster ion.

More specifically, in this example, although the cluster ion including Cl atoms and Kr atoms is used, the same result can be obtained even when, for example, the cluster ion includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

We have studied why thickness t1 of the tunnel barrier layer after the patterning becomes more than initial thickness to, and we have found this is because some of atoms or molecules comprising the cluster ion enter into the interface between the tunnel barrier layer and the magnetic layer, and makes compounds (non-conductive material) with the magnetic atoms comprising the magnetic layer.

For example, in the samples of the conditions 1, 2, and 5 explained above, the compositions of the tunnel barrier layers (central portions) after the GCIB etching were analyzed with TEM-EELS. In this analysis, Cl atoms comprising the cluster ion were detected.

This is considered to be because, when the peak value of the distribution of the cluster sizes is more than 1000 pieces, cluster ions collide with the etched surface. Along with this multiple collision, the surface temperature of the magnetoresistive element increases, and the atoms or molecules that have gained high level of energy after the collision are dispersed toward the central portion of the tunnel barrier layer, whereby these atoms or molecules make compound (in a case of Cl atoms, chlorides are made) with the magnetic layer.

In contrast, in the samples of the conditions 3 and 4 explained above, the compositions of the tunnel barrier layers (central portions) after the GCIB etching were analyzed with TEM-EELS. In this analysis, Cl atoms comprising the cluster ion were not detected.

This is considered to be because, when the peak value of the distribution of the cluster sizes is 2 pieces or more and 1000 pieces or less, the rise of the surface temperature of the magnetoresistive element due to multiple collision of the cluster ions to the etched surface is suppressed.

If the energy per one atom or molecule of the cluster ions before the collision is the same regardless of the cluster size, a cluster ion having a small cluster size is considered to be less likely to make atoms or molecules having a high level of energy after the collision under the law of conservation of energy.

On the other hand, in the monomer ion beam etching (condition 6), the ions (single-atom ions) enter into a deep position inside of the etched surface as compared with the GCIB etching, and in addition, the substrate temperature (stage temperature) is required to be at a high level, and therefore, some of ions are dispersed toward the central portion of the tunnel barrier layer, which is not desirable.

### [Relationship Between the Cluster Size and the Device Conductance]

Relationship between the cluster size and the device conductance has been further considered in the samples used to obtain the “relationship between the cluster size and the mask remaining rate” and the [relationship between the cluster size and the thickness of the tunnel barrier layer] explained above.

In this case, the device conductance means a conductance of the magnetoresistive element.

As a result, we have found that the device conductance decreases in proportional to decrease of the mask remaining rate, and increases in proportional to increase of the thickness of the tunnel barrier layer after the patterning.

For example, where the device conductance in design is about 50 μS, the (effectively measured) device conductance has decreased to about 40 μS under the conditions 2 and 5 explained above. Under the conditions, the conductances of samples manufactured under the same condition varied within a range of 2.5 to 25 μS.

One of the reasons of this is considered to be a taper formed on the hard mask layer serving as an upper electrode in relation to the mask remaining rate. Another reason is considered to be the thickness of the tunnel barrier layer after the patterning that has increased to a level more than the initial thickness in relation to the thickness of the tunnel barrier layer.

In contrast, under the conditions 3 and 4 explained above, the (effectively measured) device conductance was substantially the same as the device conductance in design, i.e., about 50 μS. In the conditions, the variation of the conductances of samples manufactured under the same condition was reduced to a range of 1 μS or less.

### [Relationship Between the Over Ratio and the Mask Remaining Rate]

As described above, the cluster sizes of the cluster ions used for the GCIB etching are distributed, and there is the peak value of the cluster size. In the explanation about the above embodiment, the peak value of the distribution of the cluster sizes is 2 pieces or more and 1000 pieces or less.

However, when the peak value of the cluster size is set in the above range, some of cluster ions may have cluster sizes beyond 1000 pieces because the cluster sizes are distributed.

Therefore, in this case, the range of the ratio of cluster ions of which cluster sizes are 2 pieces or more and 1000 pieces or less with respect to all the cluster ions generated in the GCIB etching (patterning of the magnetoresistive element), which provides the above effects, will be considered.

In this case, a term “over ratio” will be used.

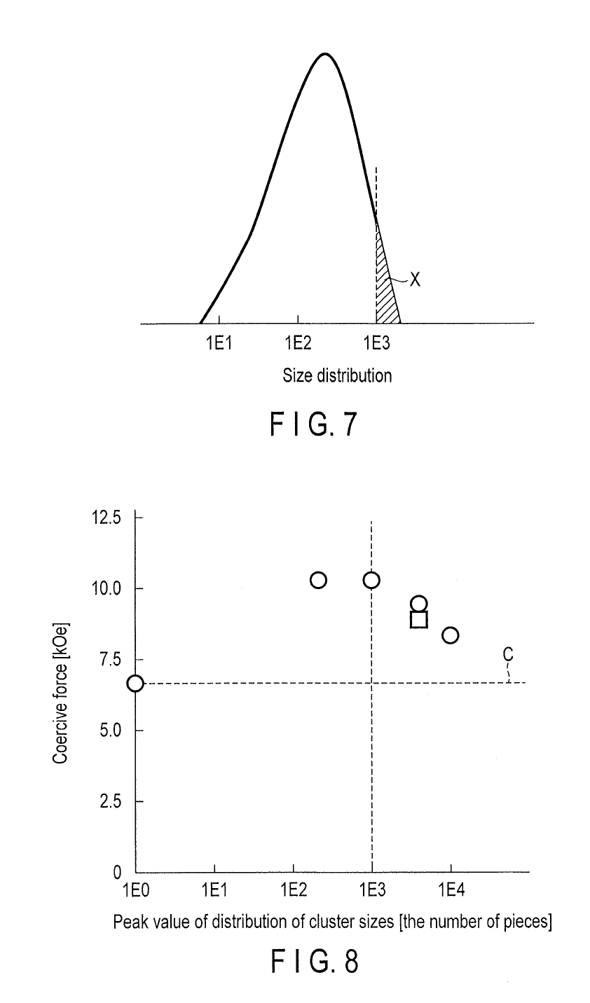

The over ratio means a ratio of cluster ions of which cluster sizes are more than 1000 pieces with respect to all the cluster ions generated in the patterning of the magnetoresistive element. More specifically, where the over ratio is X %, the cluster sizes of (100-X) % of all the cluster ions generated in the patterning of the magnetoresistive element are 2 pieces or more and 1000 pieces or less (See FIG. 7).

When the relationship between the over ratio and the mask remaining rate was studied, the relationship as illustrated in FIG. 6 was obtained.

This result is based on the above condition 3 (a case where the peak value of the distribution of the cluster sizes is 1000 pieces).

As is evident from FIG. 6, it is understood that when line A of the mask remaining rate (which is the same as line A of FIG. 3) with the monomer ion beam is adopted as a reference, a better result than that of a conventional monomer ion beam etching can be obtained where the over ratio is 0% or more and 30% or less.

More specifically, 70% or more of all the cluster ions generated in the patterning of the magnetoresistive element are aggregates of 2 to 1000 atoms or molecules. When 70% or more of all the cluster ions are aggregates of 2 to 1000 atoms or molecules, the following problems can be solved: the reduction of the processing accuracy of the magnetoresistive element, the increase in the effective thickness of the tunnel barrier, and variation in the substantial size of the magnetoresistive element.

For example, when the over ratio is 40%, the mask remaining rate was about 0.6, which is a result worse than the mask remaining rate (about 0.7) with the conventional monomer ion beam etching. In contrast, when the over ratio is 0%, the mask remaining rate was about 1.0. When the over ratio is 10%, the mask remaining rate was about 0.95. When the over ratio is 20%, the mask remaining rate was about 0.9. When the over ratio is 30%, the mask remaining rate was about 0.75. In any case, they were better results than the conventional monomer ion beam etching.

We have confirmed that all of the above results are the same when the peak value of the distribution of the cluster sizes is 2 pieces or more and 1000 pieces or less (including the condition 4).

Further, it is confirmed that the above result does not depend on the component of the cluster ion.

More specifically, in this example, although the cluster ion including Cl atoms and Kr atoms is used, the same result can be obtained even when, for example, the cluster ion includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

### [Relationship Between the Cluster Size and the Coercive Force]

Relationship between the coercive force and the cluster size of the cluster ion used for patterning the magnetoresistive element will be explained.

The magnetoresistive element serving as the sample is manufactured under the same prior condition as that of the sample used in the “relationship between the cluster size and the mask remaining rate” explained above. The conditions (condition 1 to condition 6) serving as the parameters are also the same as the above “relationship between the cluster size and the mask remaining rate”.

However, in the test described below, in order to determine the change of the coercive force of the magnetoresistive element under each of the conditions, the patterning of the magnetoresistive element is executed by an incident of Kr-inactive gas cluster from an angle of 20 degrees to 40 degrees with respect to the direction perpendicular to the substrate surface, with an acceleration voltage of 25 kV, after the patterning of the magnetoresistive element.

Under such conditions, as illustrated in FIG. 2, the magnetoresistive element is patterned by the GCIB etching using hard mask layer 15 as a mask.

Then, when the relationship between the cluster size and the coercive force was studied, the relationship as illustrated in FIG. 8 was obtained.

In this case, the second magnetic layer serving as the magnetic pinned layer (CoFeB/Tb—Co—Fe) was tested with regard to the coercive force serving as the magnetism characteristics.

As is evident from FIG. 8, it is understood that when line C of the coercive force (about 7 kOe) of the magnetic pinned layer after the patterning with the monomer ion beam is adopted as a reference, the coercive force of the magnetic pinned layer after the patterning with the cluster ion beam always results in a better result than that of a conventional monomer ion beam etching, regardless of the cluster size of the cluster ion.

For example, the coercive force of the magnetic pinned layer after the GCIB etching under the condition 1 is about 8 kOe, and the coercive force of the magnetic pinned layer after the GCIB etching under the conditions 2 and 5 is about 9 kOe, which is a result better than the conventional monomer ion beam etching. The coercive force of the magnetic pinned layer after the GCIB etching under each of the condition 3 and the condition 4 is about 10 kOe, which is a result better than the conventional monomer ion beam etching.

The coercive force where the peak value of the distribution of the cluster sizes is 2 pieces or more and 1000 pieces or less is more than the coercive force where the peak value of the distribution of the cluster sizes is more than 1000 pieces.

It is confirmed that the above result does not depend on the component of the cluster ion.

More specifically, in this example, although the cluster ion including Cl atoms and Kr atoms is used, the same result can be obtained even when, for example, the cluster ion includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

### [Relationship Between the Cluster Size and the Taper Angle]

The relationship between the cluster size of the cluster ion used for patterning the magnetoresistive element and the taper angle of the magnetoresistive element will be considered.

The magnetoresistive element serving as the sample is manufactured under the same prior condition as that of the sample used in the “relationship between the cluster size and the mask remaining rate” explained above. The conditions (condition 1 to condition 6) serving as the parameters are also the same as the above “relationship between the cluster size and the mask remaining rate”.

It should be noted that the taper angle means an angle with respect to the direction perpendicular to the substrate surface of the sidewall of the magnetoresistive element, and when the angle of the sidewall of the magnetoresistive element changes, the taper angle means an average value thereof. The taper angle depends on the mask remaining rate as illustrated in FIGS. 3 and 4.

Under such conditions, as illustrated in FIG. 2, the magnetoresistive element is patterned by the GCIB etching using the magnetoresistive element as a mask.

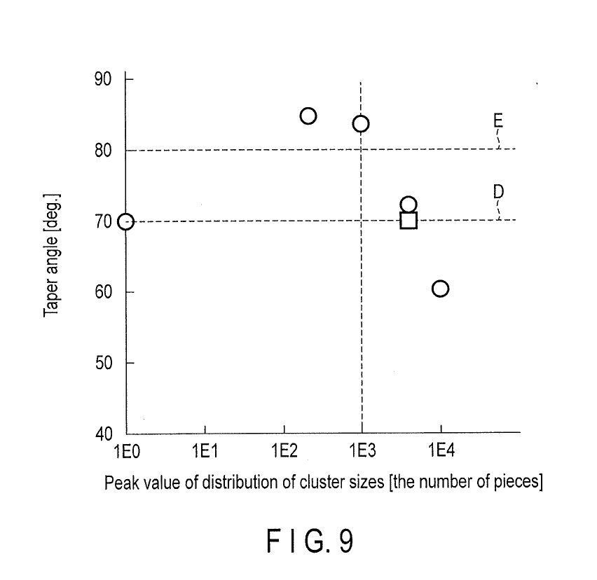

When the relationship between the cluster size and the taper angle was studied, the relationship as illustrated in FIG. 9 was obtained.

As is evident from FIG. 9, it is understood that when line D of the taper angle (about 70 degrees) of the magnetoresistive element after the patterning with the monomer ion beam is adopted as a reference, a better result than that of a conventional monomer ion beam etching can be obtained where the peak value of the distribution of the cluster sizes of cluster ions is 2 pieces or more and 1000 pieces or less.

For example, the taper angle of the magnetoresistive element layer after the GCIB etching under the condition 1 is about 60 degrees, and the taper angle of the magnetoresistive element layer after the GCIB etching under the conditions 2 and 5 is the same value as that of the monomer ion beam etching (about 70 degrees). The taper angle of the magnetoresistive element layer after the GCIB etching under each of the conditions 3 and 4 is about 85 degrees, which is a result better than the conventional monomer ion beam etching.

For example, when the characteristics of the magnetoresistive element are taken into consideration, the taper angle of the magnetoresistive element layer is desirably equal to or more than 80 degrees (line E). On the other hand, when the peak value of the distribution of the cluster sizes is 2 pieces or more and 1000 pieces or less, the taper angle of the magnetoresistive element layer is equal to or more than 80 degrees. Therefore, the peak value of the distribution of the cluster sizes is very desirably set within the range described above.

It is confirmed that the above result does not depend on the component of the cluster ion.

More specifically, in this example, although the cluster ion including Cl atoms and Kr atoms is used, the same result can be obtained even when, for example, the cluster ion includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

### [Small Cluster Size]

In the above embodiment, the cluster sizes of the cluster ion beam used for patterning the magnetoresistive element are distributed. In this case, cluster ions of extremely small cluster sizes (for example, 2 to 4) may be included.

Cluster ions of which cluster sizes are 2 pieces or more and 4 pieces or less collide with the etched surface at a high speed due to its light weight. Atoms or molecules comprising cluster ions having such small cluster sizes may have high energy after the collision as described above. The atoms or molecules having the high level of energy somewhat reduces the characteristics of the magnetoresistive element.

Therefore, in the above embodiment, cluster ions of which peak value of the distribution of the cluster sizes is 2 pieces or more and 1000 pieces or less are used, but it is desirable not to generate cluster ions having extremely small cluster sizes as much as possible.

For example, all the cluster ions generated during the patterning of the magnetoresistive element desirably have cluster sizes of 5 pieces or more. In this case, the peak value of the distribution of the cluster sizes is set within a range of 5 pieces or more and 1000 pieces or less.

### [Modification]

After the GCIB etching in the above embodiment, cluster ions of which cluster sizes are more than 1000 pieces may be emitted onto the etched surface for the purpose of removing atoms or molecules comprising gas clusters adsorbed to the etched surface and recovering the damage caused by the GCIB etching.

For example, when the Cl—Kr mixed gas clusters are used for the GCIB etching according to the above embodiment, GCIB emission is performed after the GCIB etching. The GCIB emission uses the Kr-gas clusters of which the peak value of the distribution of the cluster sizes (or the average value of the cluster sizes) is about 10000 pieces. At this occasion, the acceleration energy is generally set so that the energy per one atom or molecule is 1 eV per atom or molecule or less, e.g., 0.3 eV per atom or molecule. For example, the acceleration energy (acceleration voltage) is set at 3 kV.

With this auxiliary GCIB emission, residuals adsorbed to the etched surface (for example, Cl) can be effectively removed. At this occasion, the emission angle of the cluster ion beam is set at 10 degrees or more, so that, for example, residuals adsorbed to the sidewall portion of the magnetoresistive element (for example, Cl) can also be removed at the same time.

This has an effect of not only removing the residuals adsorbed to the sidewall portion of the magnetoresistive element and the etched surface but also giving appropriate lattice vibration to the processed surface of the magnetoresistive element. More specifically, this auxiliary GCIB emission brings about the same effect as the annealing process, and contributes to the recovery of the damage caused by the GCIB etching according to the above embodiment.

### [Others]

When the magnetoresistive element is patterned using cluster ions of which peak value of the distribution of the cluster sizes is 2 pieces or more and 1000 pieces or less, the following ancillary effects can be obtained.

The gas cluster is generated by emitting high pressure material gas into vacuum through a trumpet-shaped thin pipe called a nozzle. When the high pressure gas is emitted into vacuum, the gas is cooled to a temperature below the condensation temperature due to adiabatic expansion, and atoms or molecules are coupled with each other by Van der Waals attraction, whereby the gas cluster is generated.

The gas cluster is ionized by, for example, electronic ionization. This is a method for giving positive charge to the cluster by making use of phenomenon of electrons ejected from the cluster when the high speed electron collides with the cluster.

However, a tremendous amount of cost is required to generate a cluster size beyond 1000 pieces when the cluster ions are generated according to such method.

For example, when the energy per one atom or molecule is 10 eV per atom or molecule, an ion accelerating device of 100 kV is required to use clusters of which cluster size is 10000. In contrast, when the energy per one atom or molecule is 10 eV per atom or molecule, an ion accelerating device of 2 kV is sufficient to use clusters of which cluster size is 200.

More specifically, according to the present embodiment, for example, an ion accelerating device capable of generating an acceleration voltage of 2 kV is sufficient, and an expensive ion accelerating device capable of generating an acceleration voltage of 100 kV is not required.

As described above, the cost of the apparatus is reduced, and accordingly, the manufacturing cost of the magnetoresistive element can be suppressed. As a result, storage devices such as hard disk drives and magnetic random access memories can be provided at a low cost.

Under the conditions of the GCIB etching used in the present embodiment (condition 1 to condition 5), the energy per one atom or molecule is 5 eV per atom or molecule, but as described above, there may be distribution therein, and in such case, the average value of the energy per one atom or molecule comprising the cluster ion may be employed.

It should be noted that the energy per one atom or molecule is not limited to 5 eV per atom or molecule, but in order to ensure effectiveness of the low energy emission effect with the GCIB, the energy per one atom or molecule is desirably equal to or less than 30 eV per atom or molecule, and more desirably equal to or less than 15 eV per atom or molecule. When the energy per one atom or molecule is beyond 30 eV per atom or molecule, ion implantation effect becomes more significant.

In addition, the charge (valency) of the cluster ion is not particularly limited. The gas cluster may be monovalent ion or may be bivalent ion. The cluster ion may be positively charged or may be negatively charged.

### Second Embodiment

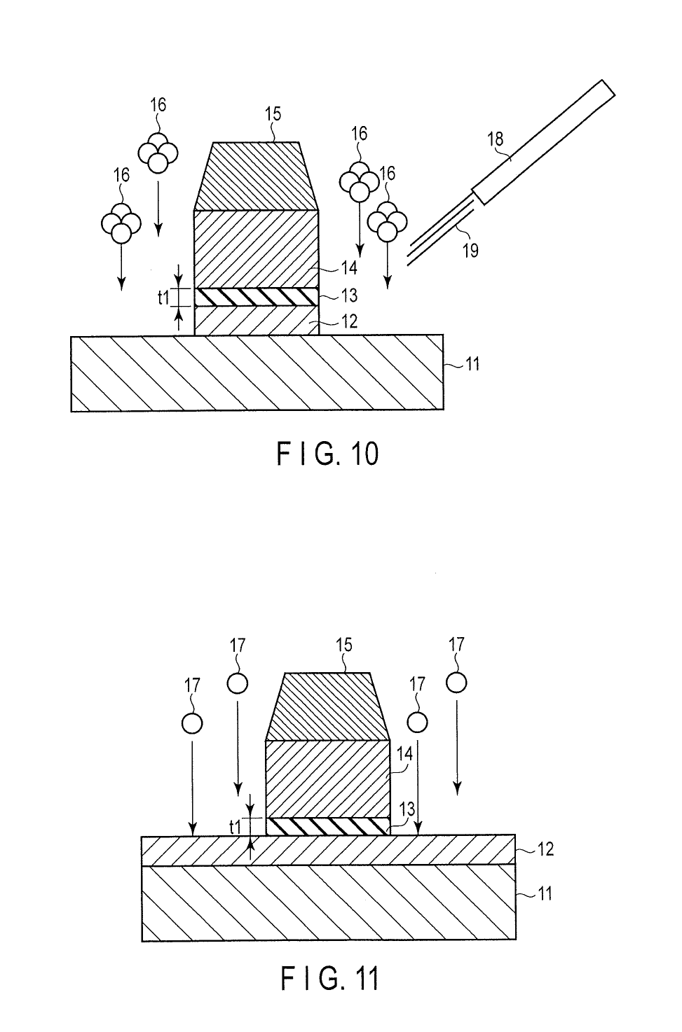

FIG. 10 is a figure illustrating the second embodiment of a manufacturing method of a magnetoresistive element.

The present embodiment is a modification of the manufacturing method according to the first embodiment. The present embodiment is different from the first embodiment in that, along with the GCIB etching, predetermined gas is provided to an etched surface and a sidewall portion of a patterned magnetoresistive element. The other features are the same as those of the first embodiment, and accordingly, description thereabout is omitted.

More specifically, as illustrated in FIG. 10, the magnetoresistive element is patterned by GCIB etching using cluster ion 16 of which the peak value of the distribution of the cluster sizes is 2 pieces or more and 1000 pieces or less.

For example, cluster ion 16 includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

Along with this, gas 19 including one molecule selected from among F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, CH₃OCH₃, HF, HNO₃, H₃PO₄, H₂SO₄, H₂O₂, and CH₃COOH is provided from gas nozzle 18 to the etched surface (emission surface of the cluster ion) and the sidewall portion of the patterned magnetoresistive element.

Accordingly, the magnetoresistive element can be patterned efficiently.

For example, a case will be considered where a reactive gas such as HCL an HF is used as gas 19 provided from gas nozzle 18. The flow rate of the gas is desirably controlled so that the partial pressures of the reactive gasses such as HCl and HF are 1×10⁻⁵ Torr to 1×10⁻⁴ Torr.

In this case, atoms or molecules comprising a reactive gas such as HCl and HF introduced during the GCIB etching are adsorbed to the etched surface (the emission surface of the cluster ion). In this state, the cluster ion (for example, O₂-cluster ion) reacts with the atoms or molecules comprising the reactive gas adsorbed to the etched surface, and this effectively etches the magnetic layer existing on the etched surface.

When the magnetic pinned layer and the magnetic free layer includes materials which are difficult to be etched such as noble metals, oxidization dissolution reaction caused by such oxidizer (for example, O₂-cluster ion) is extremely desirable to effectively etch the magnetoresistive element.

In general, in the etching using gas cluster ions, the condition of cluster formation is different in accordance with the type of the gas. Therefore, it is not easy to form a mixed cluster including reactive gases and rare gases in a mixed manner. When such mixed cluster is generated, an expensive cluster generating apparatus must be used.

Accordingly, as described above, when gas atmosphere is generated around the magnetoresistive element by providing gas 19 from the gas nozzle 18, the cluster generating apparatus may generate only clusters including a single atom or molecule, and this allows efficient etching of the magnetoresistive element at a low cost.

According to this method, even liquid gases which are difficult to form a cluster in normal circumstances and compounds of which molecular weight is large such as an organic acid can be used for the etching reaction.

It should be noted that the partial pressure of the reactive gas is desirably set in a range of 1×10⁻⁵ Torr to 1×10⁻⁴ Torr as described above.

This is because, when the partial pressure is less than this range, a sufficient amount of reactive gas cannot be provided to the etched surface, and the magnetoresistive element cannot be patterned efficiently, and when the partial pressure is higher than this range, the amount of adsorption of the atoms or molecules comprising the reactive gas to the etched surface is in saturated state, and the cluster ion cannot reach the magnetic layer of the etched surface. More specifically, the cluster ion collides with the atoms or molecules adsorbed to the etched surface, and breaks down before reaching the magnetic layer of the etched surface.

### Third Embodiment

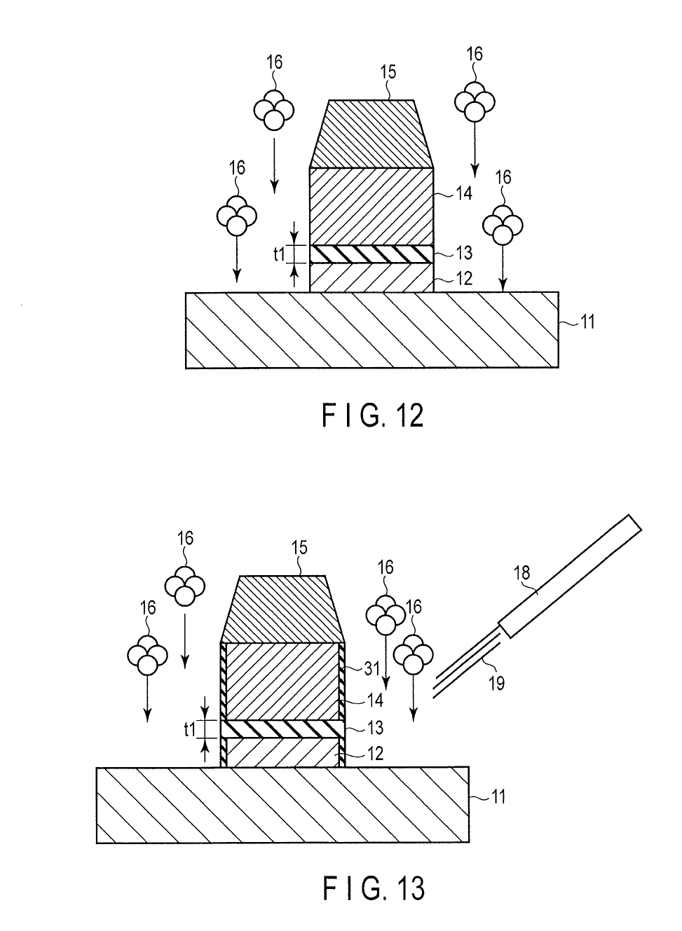

FIGS. 11 and 12 illustrate the third embodiment of a manufacturing method of a magnetoresistive element.

The present embodiment is a modification of the manufacturing method according to the first embodiment. The present embodiment is different from the first embodiment in that, first, second magnetic layer is etched by monomer ion beam etching, and thereafter, first magnetic layer is etched by GCIB etching. The other features are the same as those of the first embodiment, and accordingly, description thereabout is omitted.

First, as illustrated in FIG. 11, second magnetic layer 14 is etched by monomer ion beam etching using hard mask layer 15 as a mask.

For example, the monomer ion beam is generated by accelerating monomer ion 17 using Ar ion at acceleration energy of 200 V. The monomer ion beam etching is executed while the emission angle is changed within a range of 0 degrees to 30 degrees. In this case, the emission angle means the emission direction of the ion beam with respect to the direction perpendicular to the substrate surface.

In the present embodiment, second magnetic layer 14 and tunnel barrier layer 13 are etched by monomer ion beam etching. More specifically, the monomer ion beam etching is stopped as soon as the surface of first magnetic layer 12 is exposed.

However, the monomer ion beam etching may be stopped as soon as the surface of tunnel barrier layer 13 is exposed, so that tunnel barrier layer 13 may be left.

The monomer ion beam etching may be stopped before the surface of tunnel barrier layer 13 is exposed. More specifically, the monomer ion beam etching may be stopped during the etching of second magnetic layer 14.

For example, this etching is executed within an ion milling chamber.

Subsequently, as illustrated in FIG. 12, subsequent to the monomer ion beam etching, at least first magnetic layer 12 is etched by the GCIB etching. The GCIB etching is executed using cluster ion 16 of which peak value of the distribution of the cluster sizes is 2 pieces or more and 1000 pieces or less. The type of cluster ion 16 is the same as that of the first embodiment.

This etching is executed, for example, in the GCIB etching chamber.

As compared with the monomer ion beam etching (including RIBE), the GCIB etching provides excellent effects concerning, e.g., the magnetism characteristics and the processing accuracy of the magnetoresistive element, but there is a drawback in that the throughput is poor.

Accordingly, like the present embodiment, second magnetic layer (for example, magnetic pinned layer) 14 is patterned by the monomer ion beam etching having high throughput, and first magnetic layer (for example, magnetic free layer) 12 is patterned by the GCIB etching which is excellent in, e.g., the magnetism characteristics and the processing accuracy of the magnetoresistive element, so that the cost can be reduced due to the reduced processing time, and the magnetism characteristics and the processing accuracy of the magnetoresistive element can also be improved.

The GCIB etching according to the present embodiment is desirably executed with dose for correcting the distribution of ions dosed by the monomer ion beam etching. For example, when, in the monomer ion beam etching, the etching rate is higher in the central portion of the magnetoresistive element than in the peripheral portion, cluster ions are emitted in the GCIB etching with a scan in wafer under a condition that the etching rate is higher in the peripheral portion of the magnetoresistive element than in the central portion.

### Fourth Embodiment

FIG. 13 illustrates the fourth embodiment of a manufacturing method of a magnetoresistive element.

The present embodiment is a modification of the manufacturing method according to the third embodiment. The present embodiment is different from the third embodiment in that, along with the GCIB etching, predetermined gas is provided to an etched surface and a sidewall portion of a patterned magnetoresistive element. The other features are the same as those of the third embodiment, and accordingly, description thereabout is omitted.

More specifically, as illustrated in FIG. 13, second magnetic layer 12 is etched by GCIB etching using cluster ion 16 of which the peak value of the distribution of the cluster sizes is 2 pieces or more and 1000 pieces or less. The type of cluster ion 16 is the same as the third embodiment.

Along with this, gas 19 including one molecule selected from among F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, CH₃OCH₃, HF, HNO₃, H₃PO₄, H₂SO₄, H₂O₂, and CH₃COOH is provided from gas nozzle 18 to the etched surface (emission surface of the cluster ion) and the sidewall portion of the patterned magnetoresistive element.

Accordingly, the magnetoresistive element can be patterned efficiently.

The effect of providing predetermined gas (reactive gas) 19 in parallel with the GCIB etching is the same as the above second embodiment. More specifically, atoms or molecules comprising a reactive gas introduced during the GCIB etching are adsorbed to the etched surface (the emission surface of the cluster ion). Accordingly, the cluster ion reacts with the atoms or molecules comprising the reactive gas adsorbed to the etched surface, and this effectively etches the magnetic layer existing on the etched surface.

### Fifth Embodiment

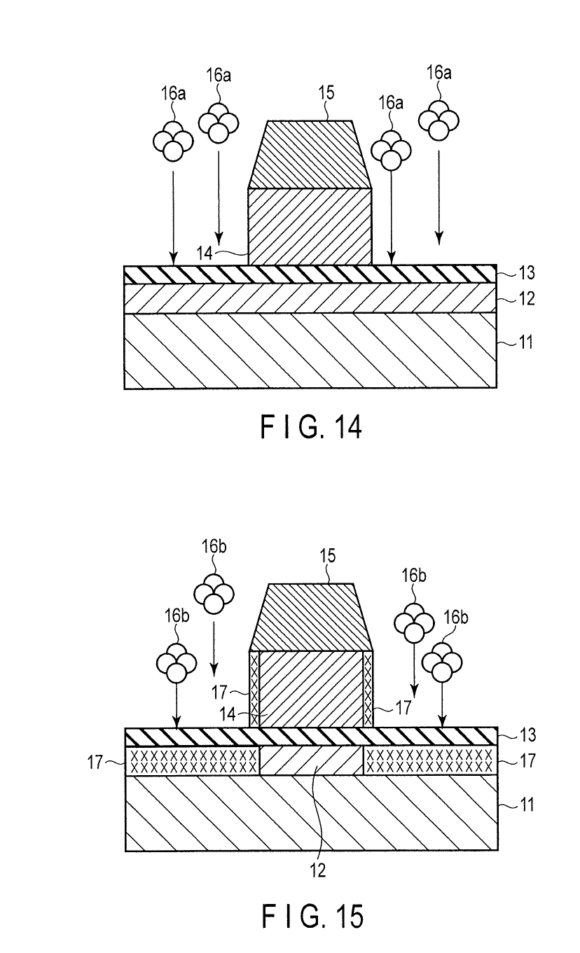

FIGS. 14 to 19 illustrate the fifth embodiment of a manufacturing method of a magnetoresistive element.

The present embodiment is a modification of the manufacturing method according to the first embodiment. The present embodiment is different from the first embodiment in that, after the patterning of the magnetoresistive element by the GCIB etching, the first and second magnetic layers are partially executed the magnetization suppression (deactivation).

First, as illustrated in FIG. 14, for example, first magnetic layer 12, tunnel barrier layer 13, second magnetic layer 14, and hard mask layer 15 are formed in order on underlayer 11 using sputtering method. For example, underlayer 11 serves as a lower electrode, and hard mask layer 15 serves as an upper electrode. For example, each of underlayer 11 and hard mask layer 15 has a metal or alloy.

First and second magnetic layers 12, 14 have one of in-face magnetization and vertical magnetization. One of first and second magnetic layers 12, 14 is a magnetic free layer of which magnetization direction is variable, and the other of first and second magnetic layers 12, 14 is a magnetic pinned layer of which magnetization direction is invariable.

When second magnetic layer 14 is used as the magnetic pinned layer, an interfacial layer may be formed in addition between tunnel barrier layer 13 and second magnetic layer 14 in the step of forming the above laminated layer structure.

When second magnetic layer 14 is used as the magnetic pinned layer, second magnetic layer 14 desirably includes a magnetic layer serving as the magnetic pinned layer and a bias magnetic field layer having an effect of cancelling leakage magnetic field from the magnetic pinned layer. Even in this case, underlayer 11 desirably includes a bias magnetic field layer, too.

Thereafter, the magnetoresistive element is patterned using lithography and cluster ion beam etching which are well-known techniques.

More specifically, using PEP, a photoresist layer is formed on hard mask layer 15, and using this photoresist layer as a mask, hard mask layer 15 is patterned. Thereafter, the photoresist layer is removed.

Subsequently, at least second magnetic layer 14 is etched by, for example, GCIB etching using hard mask layer 15 as a mask. This GCIB etching is executed using cluster ion 16a of which peak value of the distribution of the cluster sizes is 2 pieces or more and 1000 pieces or less.

For example, cluster ion 16a includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

With this GCIB etching, the patterning of the magnetoresistive element is completed.

In the present embodiment, like the above first embodiment, the magnetoresistive element is patterned by the GCIB etching. However, this may be changed to the monomer ion beam etching. This is because the feature of the present embodiment lies in the magnetization suppression explained below.

Subsequently, as illustrated in FIG. 15, first and second magnetic layers 12, 14 are partially executed the magnetization suppression by performing, for example, GCIB emission using hard mask layer 15 as a mask. This GCIB emission is executed using cluster ion 16b of which peak value of the distribution of the cluster sizes is 2 pieces or more and 1000 pieces or less.

For example, cluster ion 16b includes one molecule selected from F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one atom selected from He, Ne, Ar, Kr, Sb, and Xe.

Cluster ion 16b desirably includes nonmagnetic atom. The nonmagnetic atom is selected from, for example, Ta, W, Hf, Zr, Nb, Mo, V, Cr, Si, Ge, P, As, Sb, O, N, Cl, and F.

As a result, deactivation regions 17 are formed within first and second magnetic layers 12, 14. In the present embodiment, deactivation regions 17 are formed on the sidewall portion of second magnetic layer 14 and a portion of first magnetic layer 12 which is not covered with hard mask layer 15.

Deactivation region 17 desirably includes the above nonmagnetic atoms of which concentration is more than 20 at %.

However, this GCIB emission is for the purpose of executing the magnetization suppression of first and second magnetic layers 12, 14 with ion implantation effect of cluster ions. Therefore, for example, this is executed under process condition different from the GCIB etching for the purpose of patterning the magnetoresistive element.

More specifically, in the magnetization suppression, it is necessary to implant gas cluster ions into first and second magnetic layers 12, 14. For this reason, the energy per one atom or molecule comprising the gas cluster is desirably set at a value more than 10 eV.

For example, when the magnetization suppression process is performed using Sb-gas cluster, the peak value of the distribution of the cluster sizes is set at 500 pieces, and the acceleration voltage is set at 10 kV. At this occasion, for example, in a cluster of which peak value of cluster size is 500 pieces, the energy per one atom or molecule is 20 eV.

With this ion implantation, for example, MgO comprising the tunnel barrier layer 13 and CoFeB and Sb atoms comprising first and second magnetic layers 12, 14 are mixed with each other, and portions of first and second magnetic layers 12, 14 change into deactivation regions 17 having low electrical conductivity and low saturation magnetization amount.

As described above, portions of first and second magnetic layers 12, 14 have the magnetization suppression, so that, for example, damaged portions formed in first and second magnetic layers 12, 14 by the GCIB etching may not be used as active regions. More specifically, this can prevent variation of switching electric currents of the magnetoresistive element.

When first magnetic layer 12 is the magnetic free layer (in a case of the top pin type), the horizontal size of the magnetic free layer is reduced, the characteristics of the magnetoresistive element can be improved.

Further, when the peak value of the distribution of the cluster sizes is set at 2 pieces or more and 1000 pieces or less in this magnetization suppression (GCIB emission), it is possible to reduce the variation (edge roughness) of the substantial size of the magnetoresistive element due to the variation of dose profile of cluster ions implanted into the sidewall portion of the magnetoresistive element.

More specifically, the dose profile of cluster ions implanted into the sidewall portion of the magnetoresistive element is uniform and sharp regardless of the location.

In the manufacturing method as illustrated in FIGS. 14 and 15, etching is performed until tunnel barrier layer 13 is exposed in the pattering of the magnetoresistive element (GCIB etching). In other words, only second magnetic layer 14 is etched, but instead of this, the following modification is also possible.

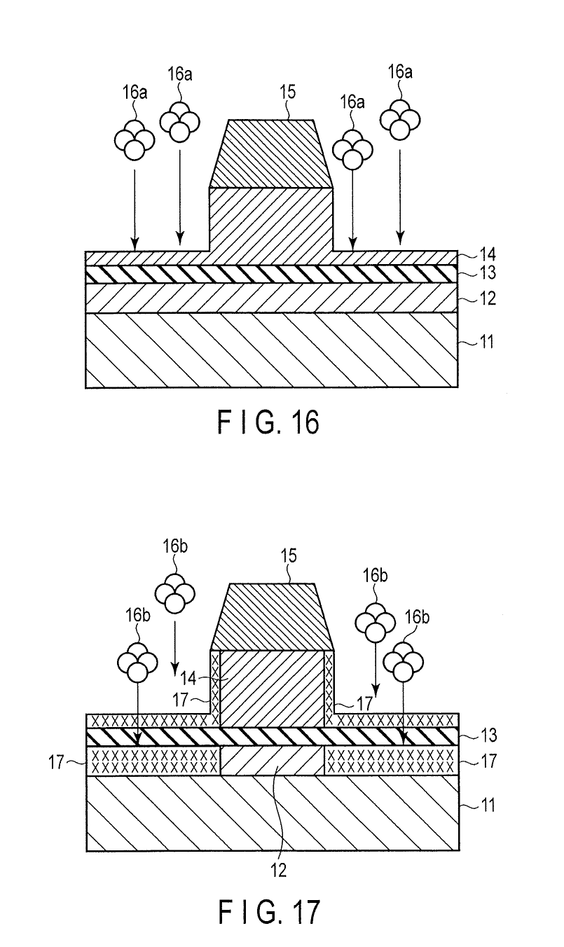

For example, as illustrated in FIG. 16, the patterning (GCIB etching) of the magnetoresistive element using gas cluster 16a is stopped before tunnel barrier layer 13 is exposed. In this case, as illustrated in FIG. 17, deactivation regions 17 formed by the GCIB emission using gas cluster 16b are formed on the sidewall portion of second magnetic layer 14 and portions of first and second magnetic layers 12, 14 which are not covered with hard mask layer 15.

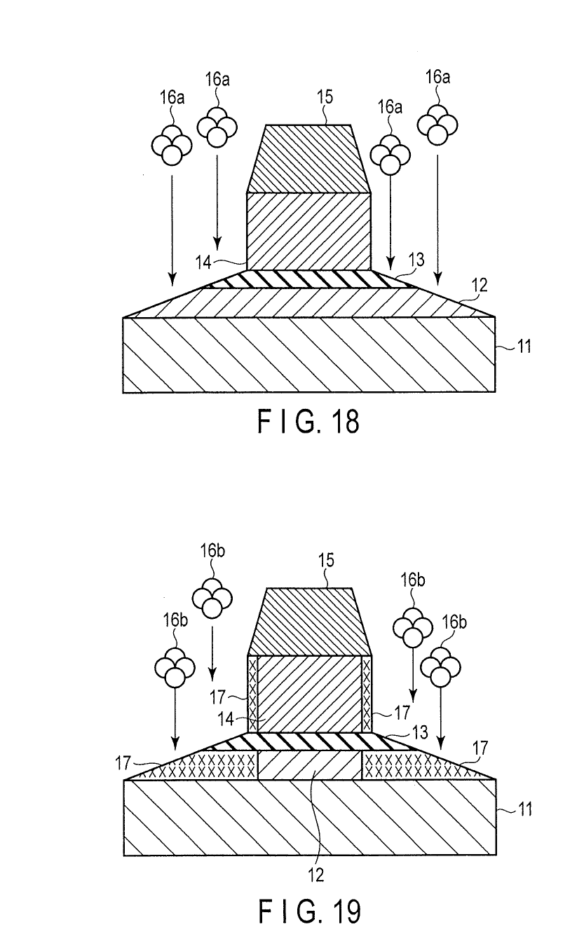

For example, as illustrated in FIG. 18, the patterning (GCIB etching) of the magnetoresistive element using gas cluster 16a can also be performed on first and second magnetic layers 12, 14. In the present embodiment, an example is shown in which the etched surface not covered with hard mask layer 15 is etched into a tapered shape (skirt shape).

In this case, as illustrated in FIG. 19, deactivation regions 17 formed by the GCIB emission using gas cluster 16b are formed on the sidewall portion of second magnetic layer 14 and portions of first and second magnetic layers 12, 14 which are not covered with hard mask layer 15.

### Sixth Embodiment

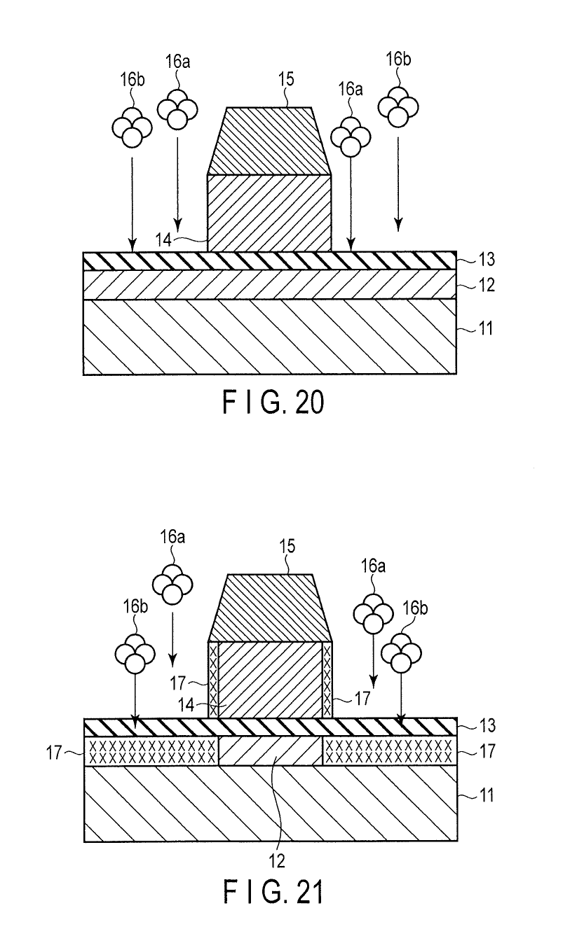

FIGS. 20 to 21 illustrate the sixth embodiment of a manufacturing method of a magnetoresistive element.

The present embodiment is a modification of the manufacturing method according to the fifth embodiment. The present embodiment is different from the fifth embodiment in that GCIB etching (patterning of a magnetoresistive element) and GCIB emission (formation of deactivation regions) are performed in parallel.

First, as illustrated in FIG. 20, for example, first magnetic layer 12, tunnel barrier layer 13, second magnetic layer 14, and hard mask layer 15 are formed in order on underlayer 11 using sputtering method.

Thereafter, the magnetoresistive element is patterned using lithography and cluster ion beam etching which are well-known techniques.

More specifically, using PEP, a photoresist layer is formed on hard mask layer 15, and using this photoresist layer as a mask, hard mask layer 15 is patterned. Thereafter, the photoresist layer is removed.

Subsequently, at least second magnetic layer 14 is etched by, for example, GCIB etching using hard mask layer 15 as a mask. In this etching, modifications as illustrated in FIGS. 16 and 17 and modifications as illustrated in FIGS. 18 and 19 are also possible.

This GCIB etching is executed using cluster ion 16a of which peak value of the distribution of the cluster sizes is 2 pieces or more and 1000 pieces or less.

As illustrated in FIG. 21, in parallel with this GCIB etching (patterning of the magnetoresistive element), first and second magnetic layers 12, 14 are partially executed the magnetization suppression by performing, for example, GCIB emission using hard mask layer 15 as a mask. This GCIB emission is executed using cluster ion 16b of which peak value of the distribution of the cluster sizes is 2 pieces or more and 1000 pieces or less.

As a result, deactivation regions 17 are formed within first and second magnetic layers 12, 14. In the present embodiment, deactivation regions 17 are formed on the sidewall portion of second magnetic layer 14 and a portion of first magnetic layer 12 which is not covered with hard mask layer 15.

In the present embodiment, gas clusters for patterning the magnetoresistive element and gas clusters for forming deactivation regions 17 are required to be generated at the same time. Therefore, the GCIB etching apparatus is expensive, but since the patterning and the magnetization suppression can be executed at the same time, the throughput can be improved.

### [Relationship Between the Cluster Size and the Dose Profile]

In the above fifth and sixth embodiments, the peak value of the distribution of the cluster sizes is set at 2 pieces or more and 1000 pieces or less in the magnetization suppression (GCIB emission), it is possible to reduce the variation (edge roughness) of the substantial size of the magnetoresistive element due to the variation of dose profile of cluster ions implanted into the sidewall portion of the magnetoresistive element.

This edge roughness will be considered.

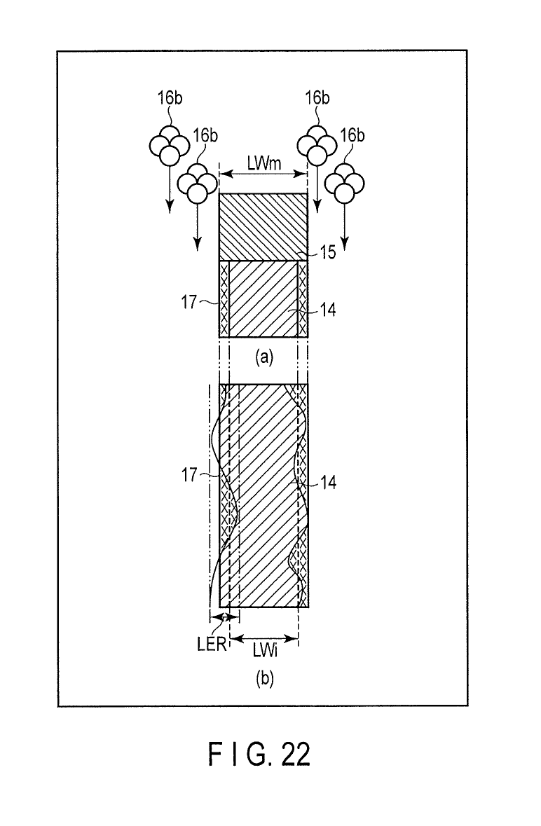

FIGS. 22 to 24 illustrate results obtained by evaluating, using 3DAP (3 dimensional atomic probe), the relationship between the cluster size and the edge roughness due to the magnetization suppression. It should be noted that the edge roughness is evaluated on the basis of the dose profile of ions ion (atoms or molecules) implanted.

As illustrated in FIG. 22, the sample includes hard mask layer 15 having a line width LWm and second magnetic layer 14 obtained by processing it with the mask. The sidewall portion of second magnetic layer 14 is executed the magnetization suppression by the gas clusters used for the above GCIB emission, and the dose profile, in the line width direction, of deactivation region 17 formed by this process is studied.

The position where the ion-implanted dose profile is 50% of the peak value is defined as an edge of deactivation region 17, i.e., an effective line threshold value (denoted as a curved line in FIG. 22).

A width (effective line width) between an average value of an effective line threshold value at one end side of second magnetic layer 14 (denoted as a dotted line in FIG. 22) and an average value of an effective line threshold value at the other end side of second magnetic layer 14 (denoted as a dotted line in FIG. 22) is denoted as LWi.

The maximum amplitude of the effective line threshold value at one end side (left side) of second magnetic layer 14 is denoted as edge roughness LER-left, and the maximum amplitude of the effective line threshold value at the other end side (right side) of second magnetic layer 14 is denoted as edge roughness LER-right.

Edge roughness LER is an average value of LER-left and LER-right.

Edge roughness LER is desirably smaller.

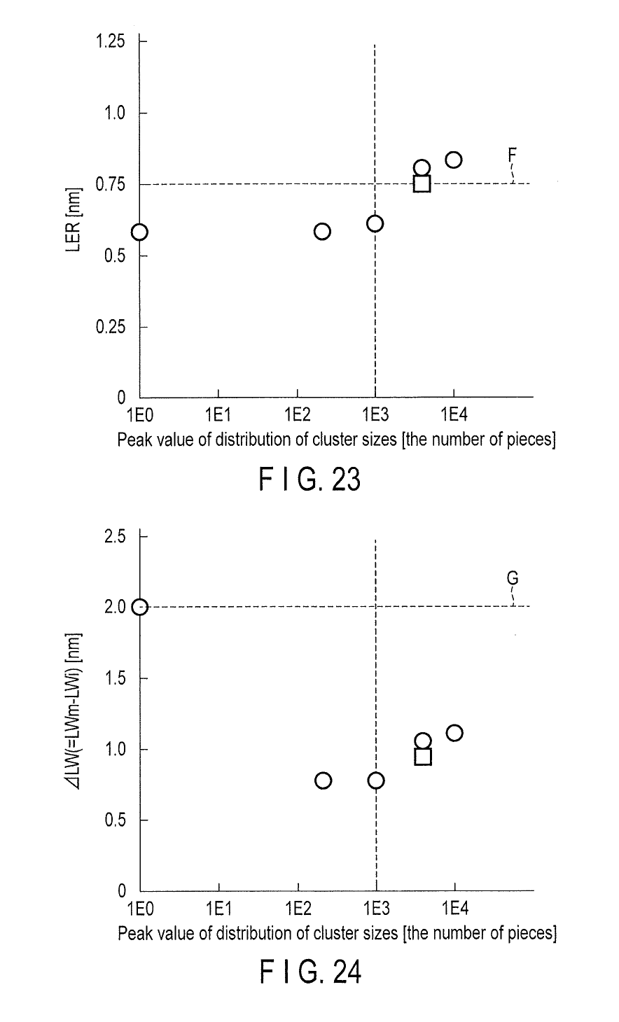

FIG. 23 is a figure illustrating relationship between the cluster size and the edge roughness.

As is evident from the figure, when the magnetization suppression is executed with monomer ion beam, edge roughness LER is about 0.6 nm.

However, in a case of the monomer ion beam, edge roughness LER is small, but since single-atom ions are used, the effective line threshold value enters into a deep position of second magnetic layer 14, and as a result, as explained later, effective line width LWi becomes small.

In contrast, according to the GCIB emission using gas clusters of which cluster size is 2 pieces or more and 1000 pieces or less, edge roughness LER is about the same as the case of the monomer ion beam, i.e., it is concentrated around 0.6 nm.

In this case, edge roughness LER is small, and in addition, as compared with the monomer ion beam, the effective line threshold value does not enter into a deep position of second magnetic layer 14. Therefore, as a result, as explained later, effective line width LWi becomes closer to line width LWm of hard mask layer 15.

Further, according to the GCIB emission using gas clusters of which cluster size is more than 1000 pieces, edge roughness LER is worse than the case of the monomer ion beam.

When the permissible value of edge roughness LER is set at 0.75 nm (line F), edge roughness LER lies within the permissible range in the GCIB emission using gas clusters of which cluster size is 2 pieces or more and 1000 pieces or less.

In order to estimate edge roughness LER, the following calculation is performed: ΔLW (=LWm−LWi).

ΔLW is a difference between line width LWm of hard mask layer 15 and effective line width LWi of second magnetic layer 14, and the magnitude of ΔLW depends on edge roughness LER.

As a result, the result as illustrated in FIG. 23 can be obtained.

As is evident from the figure, when the magnetization suppression is executed with monomer ion beam, difference ΔLW is about 2.0 nm. This is because, as described above, in the case of the monomer ion beam, edge roughness LER is small, but since single-atom ions are used, the effective line threshold value enters into a deep position of second magnetic layer 14.

In contrast, according to the GCIB emission, difference ΔLW is concentrated around 1.0 nm, and it is understood that a better result can be obtained than difference (line G) ΔLW obtained with the monomer ion beam.

When the cluster size of gas clusters used for the GCIB emission is 2 pieces or more and 1000 pieces or less, difference ΔLW is less than that of the case where the cluster size of gas clusters used for the GCIB emission is set at a value more than 1000 pieces.

For example, when the cluster size is 200 pieces and 1000 pieces (circular marks), difference ΔLW is about 0.8 nm. In contrast, when the cluster size is 5000 pieces and 10000 pieces (circular mark) and there is no size selection (rectangular marks), difference ΔLW is about 1.0 nm.

As described above, it is understood that, in order to suppress the variation (edge roughness) of the substantial size of the magnetoresistive element due to the variation of dose profile of cluster ions during the magnetization suppression, it is desirable to use the GCIB emission, and the cluster sizes of the gas clusters are desirably 2 pieces or more and 1000 pieces or less.

When difference ΔLW is configured to be generated by the GCIB emission, the variation of the characteristics of the magnetoresistive element is within the permissible range even when the horizontal size of the magnetoresistive element is equal to or less than 30 nm.

For example, when clusters including nonmagnetic atoms selected from Ta, W, Hf, Zr, Nb, Mo, V, Cr, Si, Ge, P, As, Sb, O, N, Cl, and F are used as dopants, the deactivation regions formed within the magnetic layer desirably include the above nonmagnetic atoms having a concentration of 20 at % or more as a result.

### Seventh Embodiment

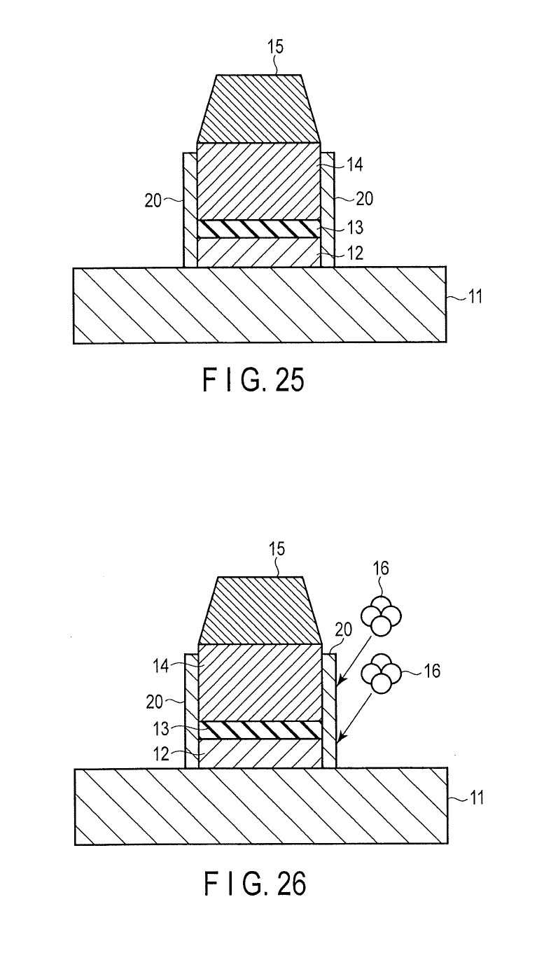

FIGS. 25 and 26 illustrate the seventh embodiment of a manufacturing method of a magnetoresistive element.

This manufacturing method relates to a technique for removing a re-deposition layer formed on sidewall portions of a magnetic free layer and a magnetic pinned layer using cluster ion beam etching after the magnetoresistive element is patterned.

First, as illustrated in FIG. 25, for example, first magnetic layer 12, tunnel barrier layer 13, second magnetic layer 14, and hard mask layer 15 are formed in order on underlayer 11 using sputtering method.

Thereafter, the magnetoresistive element is patterned using lithography and monomer ion beam etching which are well-known techniques.

More specifically, using PEP, a photoresist layer is formed on hard mask layer 15, and using this photoresist layer as a mask, hard mask layer 15 is patterned. Thereafter, the photoresist layer is removed.

Subsequently, second magnetic layer 14, tunnel barrier layer 13, and first magnetic layer 12 are etched in order by, for example, monomer ion beam etching using hard mask layer 15 as a mask.

For example, the monomer ion beam is generated by accelerating monomer ion using Ar ion at acceleration energy of 200 V. The monomer ion beam etching is executed while the emission angle is changed within a range of 0 degrees to 30 degrees. In this case, the emission angle means the emission direction of the ion beam with respect to the direction perpendicular to the substrate surface.

In the present embodiment, second magnetic layer 14, tunnel barrier layer 13, and first magnetic layer 12 are etched by monomer ion beam etching. At this occasion, on the sidewall portions of first and second magnetic layers 12, 14, re-deposition layer 20 is formed, which is generated when first and second magnetic layers 12, 14 are chipped off.

Re-deposition layer 20 includes a magnetic material comprising first and second magnetic layers 12, 14.

Subsequently, as illustrated in FIG. 26, re-deposition layer 20 adsorbed to the sidewall portions of first and second magnetic layers 12, 14 are removed by the GCIB etching. This GCIB etching is executed using cluster ion 16 of which peak value of the distribution of the cluster sizes is 2 pieces or more and 1000 pieces or less. The type of cluster ion 16 is the same as that of the first embodiment.

For example, the gas cluster ion beam is generated by accelerating, at acceleration energy of 2.5 kV, Cl gas cluster ion of which peak value of the cluster size is 500 pieces. At this occasion, the energy per Cl atom of the cluster ion of which cluster size is 500 pieces is 5 eV per atom or molecule.

The gas cluster ion beam etching is executed while the emission angle is set at about 20 degrees.

Accordingly, only re-deposition layer 20 adsorbed to the sidewall portions of first and second magnetic layers 12, 14 is selectively removed. During this GCIB etching, the stage on which the sample is placed is desirably, continuously rotated.

In the present embodiment, the method for removing re-deposition layer 20 has been explained.

Alternatively, process for efficiently removing re-deposition layer 20 by providing reactive gas or reactive ion cluster, or process for converting re-deposition layer 20 into an insulated insulating layer or process for removing re-deposition layer 20 may be employed.

Irradiating cluster including oxygen to re-deposition layer 20 on a sidewall of the magnetoresistive element is an effective.

For example, Kr-gas cluster including oxygen 20% is irradiated while the emission angle is set at about 20 degrees with respect to the direction perpendicular to the substrate surface, in condition that a peak of atomic number is 500 and an acceleration voltage is 2.5 kV. The cluster is irradiated to the re-deposition layer on the sidewall of the magnetoresistive element by a weak energy with 10 ev per one atomic element. This is because that the re-deposition layer is only changed to an insulator (an oxide) by setting the energy of the irradiation weak. In addition, an inner damage of the magnetoresistive element based on an interfusion of oxygen is reduced by oxidizing the surface of the magnetoresistive element weakly in condition of etching the re-deposition layer by the cluster.

For example, the method according to the above fourth embodiment may be employed as such process.

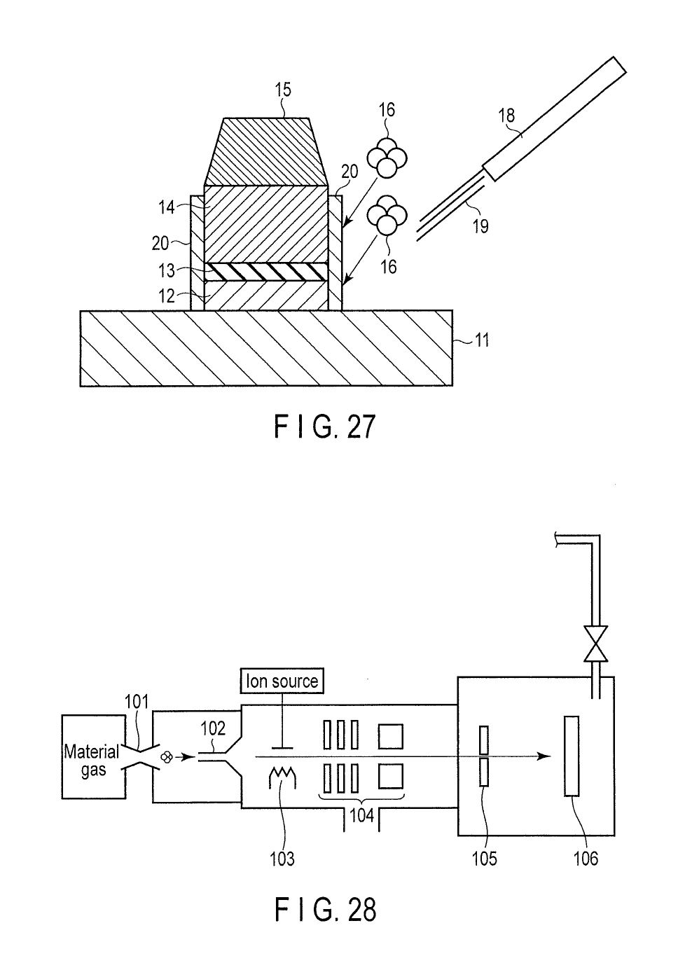

For example, as illustrated in FIG. 27, using cluster ion 16 of which peak value of the distribution of the cluster sizes is 2 pieces or more and 1000 pieces or less, reactive gas 19 is provided from gas nozzle 18 to the sidewall portion of the magnetoresistive element in parallel with the GCIB emission.

For example, the reactive gas includes one molecule selected from among F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, CH₃OCH₃, HF, HNO₃, H₃PO₄, H₂SO₄, H₂O₂, and CH₃COOH.

Accordingly, re-deposition layer 20 can be removed efficiently.

For example, when oxygen gas (O₂) 19 is provided from gas nozzle 18 in parallel with emission of the Sb-cluster ions, the tunnel barrier layer (MgO), the re-deposition layer (CoFeB), the oxygen gas (O₂), and the Sb atoms are mixed, and as a result, re-deposition layer 20 is converted into an insulating layer serving as an oxidized layer.

This effect can also be obtained even when N₂O, CO₂, CO, N₂, and the like are used as the type of gas 19.

### [Overview of GCIB Emission Apparatus]

FIG. 28 is a figure illustrating overview of a GCIB emission apparatus used in the first to seventh embodiments explained above.

High pressure material gas is emitted into vacuum through trumpet-shaped nozzle 101 of a cluster generating unit. Accordingly, atoms or molecules emitted into vacuum are cooled to a temperature below the condensation temperature due to adiabatic expansion, and atoms or molecules are coupled with each other by Van der Waals attraction, whereby the gas cluster is generated.

The gas clusters move via skimmer unit 102 to gas cluster ionizing unit 103. For example, in gas cluster ionizing unit 102, electrons are discharged from an ion source to the gas clusters, and when the electron collide with the gas cluster, more electrons are discharged from the gas cluster due to the impact of the collision.

As a result, the gas cluster becomes a positively charged ion.

The gas cluster ions thus formed are accelerated by ion retrieving/accelerating unit 104. The acceleration voltage of ion or the acceleration energy given to cluster is set by ion retrieving/accelerating unit 104.

Then, gas cluster ions accelerated are emitted onto the sample 106 using emission unit (lens unit) 105 after execution of alignment of emission position.

### [Example of Application]

The magnetoresistive element according to each embodiment explained above can be applied to a storage device such as a magnetic head of a high recording density hard disk drive (HDD) and a memory cell of a highly integrated magnetic random access memory (MRAM).

In this case, a case where the manufacturing method of each embodiment is applied to the magnetic memory will be explained.

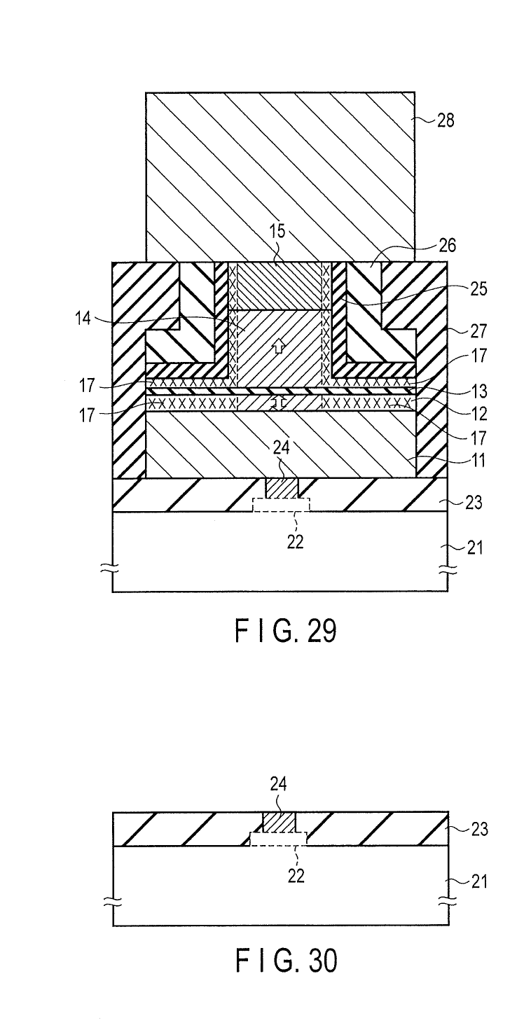

FIG. 29 illustrates the magnetic memory.

This magnetic memory is, for example, a magnetic random access memory (MRAM). The MRAM includes at least one memory cell. When the MRAM includes memory cells, the memory cells are arranged in a matrix form, which constitutes a memory cell array. One memory cell includes a magnetoresistive element, and FIG. 29 illustrates a magnetoresistive element.

Device 22 is provided on semiconductor substrate 21. For example, when one memory cell has one switch device and one magnetoresistive element, device 22 is a switch device such as an MOS transistor. Device 22 is covered with layer insulating layer 23, and contact plug 24 is electrically connected to device 22.

Underlayer 11 is provided on contact plug 24. Underlayer 11 may function as a lower electrode of the magnetoresistive element, or a lower electrode may be provided separately in addition to underlayer 11.

First magnetic layer (magnetic free layer) 12 is provided on underlayer 11. First magnetic layer 12 is arranged such that the magnetization direction thereof is substantially perpendicular to the film surface and is variable. Tunnel barrier layer 13 is arranged on magnetic free layer 12. For example, underlayer 11 is a layer required to set the magnetization direction of magnetic free layer 12 substantially perpendicular to the film surface.

For example, magnetic free layer 12 has a structure obtained by laminating, six times, a layer including Pd (thickness=0.4 nm) and Co (thickness=0.4 nm), and includes Ta (thickness=0.3 nm) and CoFeB (thickness=1 nm) which are formed on this structure.

For example, tunnel barrier layer 13 has a body-centered cubic lattice (BCC) structure, and includes an Mgo layer (thickness=1 nm) arranged in (001) plane.

Magnetic pinned layer 14 is arranged on tunnel barrier layer 13. Magnetic pinned layer 14 is arranged such that the magnetization direction thereof is substantially perpendicular to the film surface and is invariable. For example, magnetic pinned layer 14 includes CoFeB (thickness=1 nm). Further, magnetic pinned layer 14 may include Ta (thickness=4 nm), Co (thickness=4 nm), Pt (thickness=6 nm)/Co (thickness=4 nm).

Hard mask layer 15 is arranged on magnetic pinned layer 14. For example, hard mask layer 15 includes a Ta layer. Hard mask layer 15 may function as an upper electrode of the magnetoresistive element, or an upper electrode may be provided separately in addition to hard mask layer 15. In the present embodiment, magnetic pinned layer 14 is patterned using hard mask layer 15 as a mask, but magnetic free layer 12 and tunnel barrier layer 13 are not patterned.

In this case, “magnetic free layer 12 and magnetic pinned layer 14 are arranged such that the magnetization direction thereof is substantially perpendicular to the film surface” means not only a case where the magnetization direction is perpendicular to the film surface but also a range in which the magnetization state (parallel/not parallel) of magnetic free layer 12 and magnetic pinned layer 14 can be determined (for example, range in which the magnetization direction is θ (45 degrees<θ≦90 degrees (vertical)) with respect to the film surface).

For example, magnetic free layer 12 includes deactivation region (the region which is executed the magnetization suppression) 17. A portion actually functioning as the magnetic free layer of the magnetoresistive element is an active region (the region which is not executed the magnetization suppression) other than deactivation region 17.

The magnetoresistive element is constituted by magnetic free layer 12, tunnel barrier layer 13, and magnetic pinned layer 14. Then, a spin implantation electric current is passed through the magnetoresistive element in a direction perpendicular to the film surface, so that the magnetization of magnetic free layer 12 is reversed.

The spin implantation electric current generates spin-polarized electrons, and the angular momentum is transmitted to the electrons within magnetic free layer 12, whereby the magnetization reversal (spin direction) is reversed. According to this method, the direction of the spin implantation electric current is controlled, so that the magnetization direction of magnetic free layer 12 can be controlled.

In contrast, the magnetization direction of magnetic pinned layer 14 is invariable. In this case, “the magnetization direction of magnetic pinned layer 14 is invariable” means that, when the magnetization reversal electric current for reversing the magnetization direction of magnetic free layer 12 is passed through magnetic pinned layer 14, the magnetization direction of the magnetic pinned layer 14 does not change.

Therefore, when a magnetic layer of which magnetization reversal electric current is low is used as magnetic free layer 12, and magnetic layer of which magnetization reversal electric current is high is used as magnetic pinned layer 14, magnetic free layer 12 of which magnetization direction is variable and magnetic pinned layer 14 of which magnetization direction is invariable can be achieved.

When the magnetization reversal is caused by the spin-polarized electrons, the magnetization reversal electric current is proportional to an attenuation factor, anisotropic magnetic field, and the volume of the magnetoresistive element, and therefore, by adjusting them appropriately, a difference can be made in the magnetization reversal electric current between magnetic free layer 12 and magnetic pinned layer 14.

An arrow in FIG. 29 denotes the magnetization direction. The magnetization direction of magnetic pinned layer 14 is an example and may be downward instead of upward.

Since each of magnetic free layer 12 and magnetic pinned layer 14 has magnetic anisotropy substantially perpendicular to the film surface, the axis of easy magnetization thereof is substantially perpendicular to the film surface (hereinafter, vertical magnetization). More specifically, in the magnetoresistive element, each of the magnetization directions of magnetic free layer 12 and magnetic pinned layer 14 is substantially perpendicular to the film surface. In other words, the magnetoresistive element is a so-called vertical magnetization type magnetoresistive element.

It should be noted that, when a certain macro sized ferromagnet is assumed, the axis of easy magnetization means a direction in which the internal energy becomes the least when spontaneous magnetization is in that direction while no external magnetic field is given. On the other hand, when a certain macro sized ferromagnet is assumed, the axis of hard magnetization means a direction in which the internal energy becomes the highest when spontaneous magnetization is in that direction while no external magnetic field is given.

When magnetic pinned layer 14 includes multiple layers, insulating layers 25, 26 are provided to cover the sidewall thereof without any gap on the sidewall of each layer. For example, layer insulating layer 27 is Si oxide (SiO₂) or Si nitride (SiN). The upper surface of layer insulating layer 27 is planarized, and the upper surface of hard mask layer 15 is exposed from layer insulating layer 27.

Conductive line (for example, bit line) 28 is connected to hard mask layer (electrode layer) 15. Conductive line 28 is, for example, aluminum (Al) or copper (Cu).

In the above magnetic memory, underlayer 11 can be constituted by, for example, a thick metallic layer serving as a lower electrode and a buffer layer for setting the magnetization direction of magnetic free layer 12 substantially perpendicular to the film surface. Underlayer 11 may have a laminated layer structure made by laminating metallic layers such as tantalum (Ta), copper (Cu), Ru (Ru), and iridium (Ir).

Magnetic free layer 12 and magnetic pinned layer 14 may be, for example, (1) a ferromagnetic material having L₁₀ structure or L₁₁ structure such as FePd, FePt, CoPd, and CoPt, (2) a ferrimagnetic material such as TbCoFe, and (3) an artificial lattice made of a laminated layer structure including a magnetic material such as NiFe, Co and a nonmagnetic material such as Cu, Pd, Pt.

For example, tunnel barrier layer 13 may be magnesium oxide (MgO), Mg nitride, aluminum oxide (Al₂O₃), Al nitride, or a laminated layer structure thereof.

Hard mask layer 15 may be a metal such as tantalum (Ta) and tungsten (W) or a conductive compound such as Ti nitride (TiN), TiSi nitride (TiSiN), tantalum Si nitride (TaSiN).

The magnetization direction of each of magnetic free layer 12 and magnetic pinned layer 14 may be substantially parallel to the film surface.

In this case, “magnetic free layer 12 and magnetic pinned layer 14 are arranged such that the magnetization direction thereof is substantially parallel to the film surface” means not only a case where the magnetization direction is parallel to the film surface but also a range in which the magnetization state (parallel/not parallel) of magnetic free layer 12 and magnetic pinned layer 14 can be determined (for example, range in which the magnetization direction is θ (0 degrees (parallel)<θ≦45 degrees) with respect to the film surface).

In this case, each of magnetic free layer 12 and magnetic pinned layer 14 has magnetic anisotropy substantially parallel to the film surface, the axis of easy magnetization thereof is substantially parallel to the film surface (hereinafter, in-face magnetization). More specifically, in the magnetoresistive element, each of the magnetization directions of magnetic free layer 12 and magnetic pinned layer 14 is substantially parallel to the film surface. In other words, the magnetoresistive element is a so-called in-face magnetization type magnetoresistive element.

An example of magnetic free layer 12 and magnetic pinned layer 14 achieving the in-face magnetization includes, for example, a magnetic metal including at least one atom selected from the group consisting of iron (Fe), cobalt (Co), nickel (Ni), manganese (Mn), chromium (Cr).

Whether to employ the vertical magnetization type or the in-face magnetization type as the magnetoresistive element can be chosen as necessary in accordance with the required characteristics of the MRAM.

The above magnetic memory employs a spin implantation magnetization reversal method. More specifically, the above magnetic memory employs a method in which the spin implantation electric current serving as write electric current is passed through the magnetoresistive element, and using the spin polarized electrons generated thereby, the magnetization reversal is executed.

In this case, in usual case, the leakage magnetic field given from the magnetic pinned layer acting on the magnetic free layer acts to set the magnetization of the magnetic free layer in a direction parallel to the magnetization of the magnetic pinned layer. However, when the magnetic free layer is larger than the magnetic pinned layer, the leakage magnetic field given by the magnetic pinned layer nonuniformly affects the magnetic free layer, and therefore, there is a problem in that the magnetization reversal characteristics by the spin implantation are deteriorated. For this reason, the size of the magnetic free layer is desirably the same as the size of the magnetic pinned layer or is desirably smaller than that.

In a magnetoresistive element employing a spin implantation magnetization reversal method and using a vertical magnetization film in particular, the magnetism characteristics can be improved when the magnetic free layer is formed at the lower side (substrate side).

FIGS. 30 to 38 illustrate a manufacturing method of the above magnetic memory.

First, as illustrated in FIG. 30, device 22 is formed on semiconductor substrate 21. Device 22 includes a switch device such as an MOS transistor and a conductive line such as FEOL (Front End Of Line). In addition, layer insulating layer 23 is formed on device 22, and contact plug 24 reaching device 22 is formed within layer insulating layer 23.

Thereafter, the upper surface of layer insulating layer 23 is planarized by CMP (Chemical Mechanical Polishing) and etchback. For example, layer insulating layer 23 is Si oxide (SiO₂), and for example, contact plug 24 is tungsten (W).

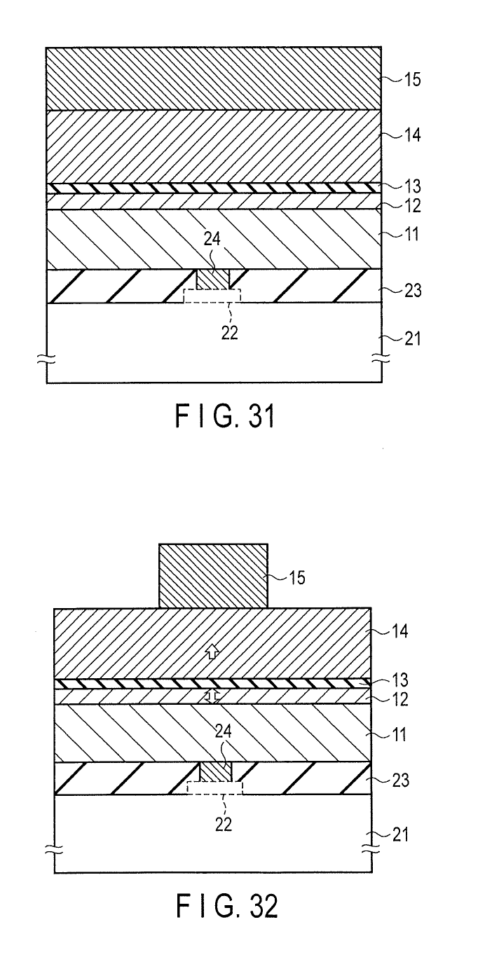

Subsequently, as illustrated in FIG. 31, for example, underlayer 11, magnetic free layer 12, tunnel barrier layer 13, magnetic pinned layer 14, and hard mask layer 15 are formed in order on contact plug 24 using sputtering method.

For example, underlayer 11 is a layer required to set the magnetization direction of magnetic free layer 12 in a direction perpendicular to the film surface (the upper surface of the underlayer). For example, magnetic free layer 12 has a structure obtained by laminating, six times, a layer including Pd (thickness=0.4 nm) and Co (thickness=0.4 nm), and includes Ta (thickness=0.3 nm) and CoFeB (thickness=1 nm) which are formed on this structure.

For example, tunnel barrier layer 13 has a body-centered cubic lattice (BCC) structure, and includes an MgO layer (thickness=1 nm) arranged in (001) plane.

For example, magnetic pinned layer 14 includes CoFeB (thickness=1 nm). Further, magnetic pinned layer 14 may include Ta (thickness=4 nm), Co (thickness=4 nm), Pt (thickness=6 nm)/Co (thickness=4 nm). In this case, the magnetic bias of the magnetoresistive element can be adjusted.

For example, hard mask layer 15 includes a tantalum (Ta) layer.

Magnetic pinned layer 14 may include a bias magnetic field layer having an effect of cancelling leakage magnetic field therefrom. In addition, underlayer 11 may also include a bias magnetic field layer.

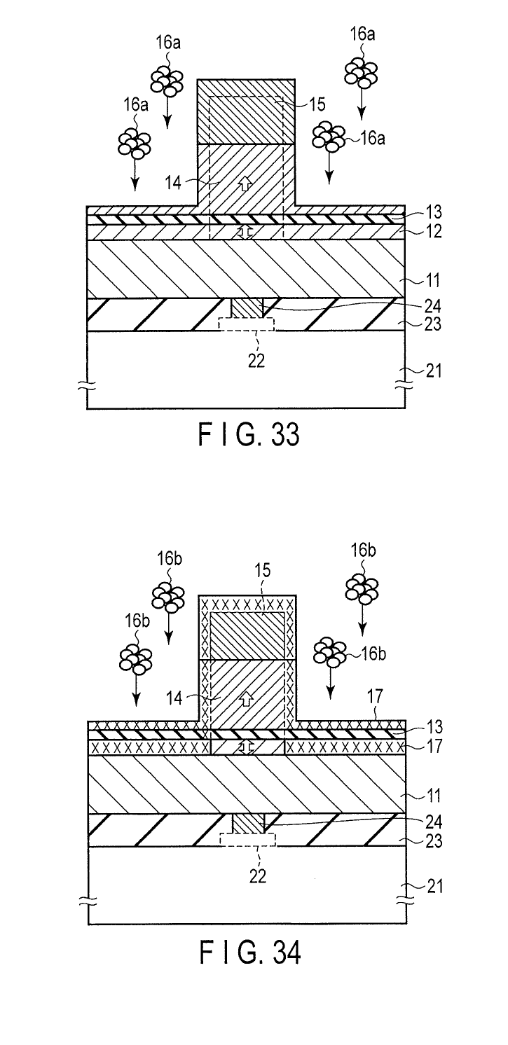

Subsequently, as illustrated in FIGS. 32 and 33, the magnetoresistive element is patterned using lithography and gas cluster ion beam etching which are well-known techniques.

More specifically, as illustrated in FIG. 32, using PEP (Photo engraving process), a photoresist layer is formed on hard mask layer 15, and using this photoresist layer as a mask, hard mask layer 15 is patterned. Thereafter, the photoresist layer is removed.

Subsequently, as illustrated in FIG. 33, using hard mask layer 15 as a mask, magnetic pinned layer 14 is patterned by, for example, GCIB etching in which gas cluster 16a of which cluster size is 2 pieces or more and 1000 pieces or less is used.

In this case, magnetic pinned layer 14 may be etched until tunnel barrier layer 13 is exposed, or in the etched region, tunnel barrier layer 13 may not be exposed while magnetic pinned layer 14 is left on tunnel barrier layer 13.

In general, tunnel barrier layer 13 is extremely thin, and it is difficult to stop etching when tunnel barrier layer 13 is exposed. When over etching into magnetic free layer 12 is taken into consideration, etching of magnetic pinned layer 14 is desirably stopped before completion (before tunnel barrier layer 13 is exposed).

Subsequently, as illustrated in FIG. 34, using hard mask layer 15 as a mask, GCIB emission for the magnetization suppression is executed on magnetic free layer 12 and magnetic pinned layer 14.

For example, cluster 16b used for the GCIB emission includes one of N₂O, O, N, F, Cl, Ru, Si, B, C, Zr, Tb, Ti, P, and As. Where the total number of clusters used for the GCIB emission is denoted as N, and the average number of atoms of clusters is denoted as A, the following expression is desirably satisfied: N×A>1×10¹⁷ cm⁻².

In the present embodiment, the cluster used for the GCIB emission is N cluster, and for example, ion beam is emitted thereon at an acceleration voltage of 5 kV. The total number N of N clusters is, for example, 1×10¹⁴ cm⁻². The average number of atoms A of clusters is, for example, 2000. N×A is, for example, 2×10¹⁷ cm⁻². At this occasion, the average energy per atom is 2.5 eV.

With this GCIB emission, some of magnetic free layer 12 and magnetic pinned layer 14 are executed the magnetization suppression to increase resistance. These portions become magnetically and electrically deactivation regions (deactivation regions) 17. Deactivation regions 17 are formed in portions which are not covered with hard mask layer 15, but deactivation regions 17 are somewhat formed in portions covered with hard mask layer 15.

In addition, by emitting clusters including oxygen at the same time or in order, the electric conductivity of the emission portion can be reliably reduced, and therefore, this can prevent reduction of write/read efficiency due to the electric current leak. When the deactivation portion of magnetic pinned layer 14 is removed by the GCIB emission, the electric current leak can be reliably prevented, and the write/read efficiency can be improved.

Thereafter, using the GCIB or etching means such as the monomer ion beam, deactivation region 17 can be physically removed.

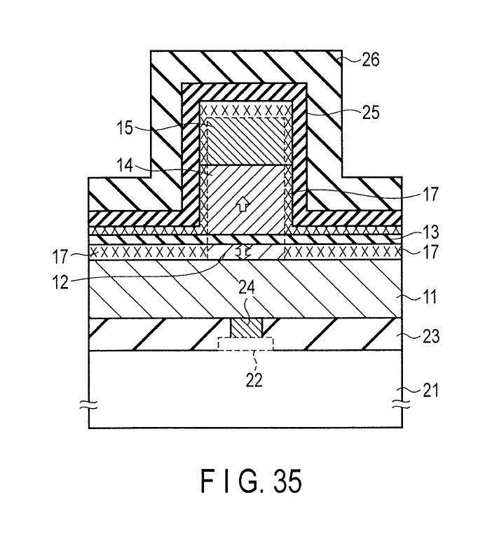

Subsequently, as illustrated in FIG. 35, insulating layers 25, 26 covering magnetic pinned layer 14 and hard mask layer 15 are formed. When magnetic pinned layer 14 includes multiple layers, insulating layers 25, 26 are provided to cover the sidewall thereof without any gap on the sidewall of each layer.

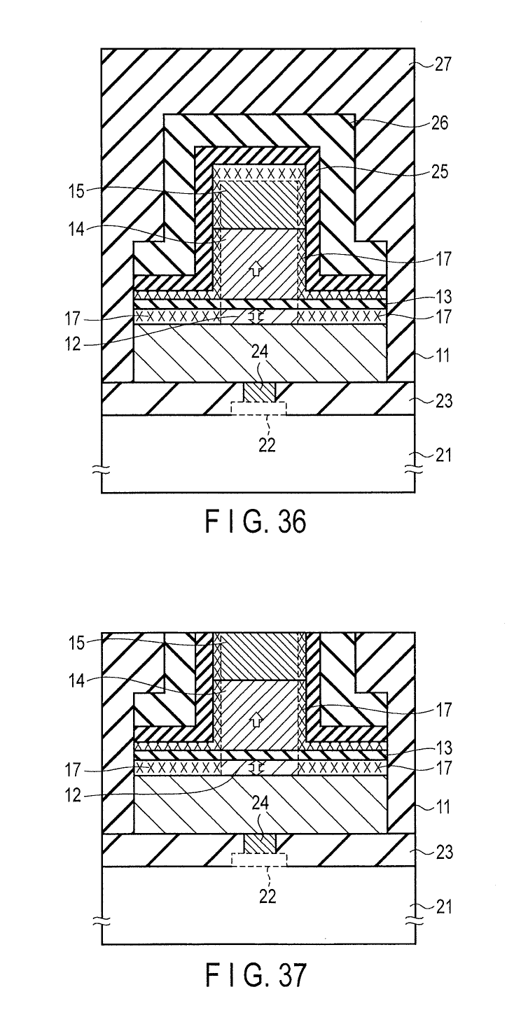

Subsequently, as illustrated in FIG. 36, the magnetoresistive element is patterned using lithography and etching which are well-known techniques. In this patterning, magnetic free layer 12, tunnel barrier layer 13, and magnetic pinned layer 14 are patterned.

More specifically, after the photoresist layer is formed on insulating layer 26, insulating layers 25, 26, magnetic pinned layer 14, tunnel barrier layer 13, magnetic free layer 12, and underlayer 11 are etched by RIBE using the photoresist layer as a mask, and independent magnetoresistive elements are formed.

In this case, in the patterning process of the magnetoresistive element at this stage, deactivation regions 17 of magnetic free layer 12 and magnetic pinned layer 14 are patterned, and if metallic re-deposited materials are adhered to the sidewall of magnetic free layer 12/tunnel barrier layer 13/magnetic pinned layer 14, no problem would be caused.

Thereafter, layer insulating layer 27 covering the magnetoresistive element is formed. For example, layer insulating layer 27 is Si oxide (SiO₂) or Si nitride (SiN). Thereafter, using the CMP method, the upper surface of the layer insulating layer 27 is planarized.

Subsequently, as illustrated in FIG. 37, using the CMP method, the upper surface of the layer insulating layer 27 is further continuously grinded, and the upper surface of hard mask layer 15 is exposed.

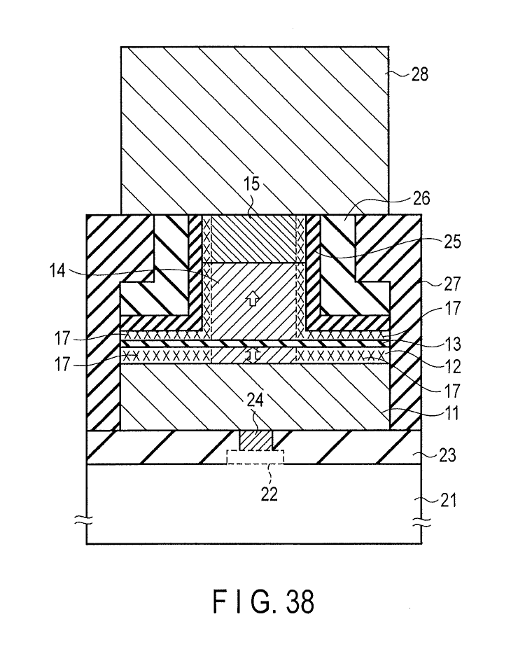

Finally, as illustrated in FIG. 38, conductive line 28 connected to hard mask layer 15 is formed on layer insulating layer 27. For example, conductive line 28 is aluminum (Al) or copper (Cu).

When the magnetoresistive element of the magnetic random access memory (MRAM) is formed according to the above manufacturing method, the margin of the electric current density required for the spin implantation magnetization reversal can be increased, and the characteristics of the spin implantation magnetization reversal can be improved. In addition, the yield of the magnetoresistive element can be improved.

It should be noted that the magnetoresistive element may be a top pin type or a bottom pin type. The present embodiment achieves significant effect for, e.g., the processing of the magnetoresistive element, but the present embodiment can also be applied to processing of other metals, semiconductors, insulators, and the like.

For example, a layer to be patterned (metals, semiconductors, insulators, and the like) is formed, and a hard mask layer is formed on the layer to be patterned. Then, using the hard mask layer as a mask, the layer to be patterned is patterned by cluster ion beam.

At this occasion, the cluster sizes of cluster ions comprising the cluster ion beam are distributed as described in the above embodiment, and the peak value of the distribution of the cluster sizes is set at 2 pieces or more and 1000 pieces or less.

Therefore, not only the processing accuracy of the layer to be patterned but also the characteristics are improved at the same time.

### CONCLUSION

According to the embodiments, the new manufacturing method of the magnetoresistive element can be achieved using the cluster ion beam.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1-23. (canceled)

24. A method of manufacturing a magnetoresistive element, the method comprising:
forming a first magnetic layer;
forming an insulating layer on the first magnetic layer;
forming a second magnetic layer on the insulating layer;
forming a mask layer on the second magnetic layer; and
partially deactivating the first magnetic layer or the second magnetic layer and etching the first magnetic layer or the second magnetic layer by a cluster ion beam including cluster ions, using the mask layer as a mask.

25. The method of claim 24, wherein the cluster ions include nonmagnetic atoms, and magnetization of each of the first and second magnetic layers is suppressed by the cluster ion beam.

26. The method of claim 25, wherein the nonmagnetic atoms having a concentration of more than 20 at % are included in an area which is deactivated by the cluster ion beam.

27. The method of claim 25, wherein
the nonmagnetic atoms include one of Ta, W, Hf, Zr, Nb, Mo, V, Cr, Si, Ge, P, As, Sb, O, N, Cl and F.

28. The method of claim 24, wherein cluster sizes of the cluster ions are distributed, and a peak value of the distribution of the cluster sizes is 2 pieces or more and 1000 pieces or less.

29. The method of claim 24, wherein after the cluster ion beam is emitted, auxiliary emission is executed using cluster ions of which cluster sizes are more than 1000 pieces and of which energy per one atom or molecule is equal to or less than 1 eV per atom or molecule.

30. The method of claim 24, wherein
the cluster ions include one of F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one of He, Ne, Ar, Kr, Sb, and Xe.

31. The method of claim 24, wherein
the magnetoresistive element of which horizontal size is equal to or less than 30 nm is formed by the cluster ion beam.

32. A method of manufacturing a magnetoresistive element, the method comprising:
forming a first magnetic layer;
forming an insulating layer on the first magnetic layer;
forming a second magnetic layer on the insulating layer;
forming a mask layer on the second magnetic layer; and
partially deactivating the first and second magnetic layers by a cluster ion beam including cluster ions after etching at least the second magnetic layer, using the mask layer as a mask.

33. The method of claim 32, wherein the cluster ions include nonmagnetic atoms, and magnetization of each of the first and second magnetic layers is suppressed by the cluster ion beam.

34. The method of claim 33, wherein the nonmagnetic atoms having a concentration of more than 20 at % are included in an area which is deactivated by the cluster ion beam.

35. The method of claim 11, wherein the nonmagnetic atoms include one of Ta, W, Hf, Zr, Nb, Mo, V, Cr, Si, Ge, P, As, Sb, O, N, Cl and F.

36. The method of claim 32, wherein cluster sizes of the cluster ions are distributed, and a peak value of the distribution of the cluster sizes is 2 pieces or more and 1000 pieces or less.

37. The method of claim 32, wherein the cluster ions include one of F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one of He, Ne, Ar, Kr, Sb, and Xe.

38. A method of manufacturing a magnetoresistive element, the method comprising:
forming a first magnetic layer;
forming an insulating layer on the first magnetic layer;
forming a second magnetic layer on the insulating layer;
forming a mask layer on the second magnetic layer; and
partially deactivating the first magnetic layer by a cluster ion beam including cluster ions after etching the second magnetic layer, using the mask layer as a mask.

39. The method of claim 38, wherein the cluster ions include nonmagnetic atoms, and magnetization of the first magnetic layer is suppressed by the cluster ion beam.

40. The method of claim 39, wherein the nonmagnetic atoms having a concentration of more than 20 at % are included in an area which is deactivated by the cluster ion beam.

41. The method of claim 39, wherein the nonmagnetic atoms include one of Ta, W, Hf, Zr, Nb, Mo, V, Cr, Si, Ge, P, As, Sb, O, N, Cl and F.

42. The method of claim 38, wherein cluster sizes of the cluster ions are distributed, and a peak value of the distribution of the cluster sizes is 2 pieces or more and 1000 pieces or less.

43. The method of claim 38, wherein the cluster ions include one of F₂, CHF₃, CF₄, C₂F₆, C₂HF₅, CHClF₂, NF₃, SF₆, ClF₃, Cl₂, HCl, CClF₃, CHCl₃, CBrF₃, Br₂, CO₂, CO, N₂, O₂, NH₃, N₂O, and CH₃OCH₃, or one of He, Ne, Ar, Kr, Sb, and Xe.
